(19) United States
(12) Patent Application Publication
(10) Pub. No.: US 2024/0379699 A1
(43) Pub. Date: Nov. 14, 2024

(54) PHOTODETECTOR, METHOD OF MANUFACTURING PHOTODETECTOR, AND ELECTRONIC APPARATUS

(71) Applicant: SONY SEMICONDUCTOR SOLUTIONS CORPORATION, Kanagawa (JP)

(72) Inventors: Nobuya NAKAZAKI, Kanagawa (JP); Hideki MINARI, Kanagawa (JP)

(73) Assignee: SONY SEMICONDUCTOR SOLUTIONS CORPORATION, Kanagawa (JP)

(21) Appl. No.: 18/292,313

(22) PCT Filed: Mar. 16, 2022
(86) PCT No.: PCT/JP2022/011862

§ 371 Date: Jan. 25, 2024

(30) Foreign Application Priority Data
Aug. 6, 2021 (JP) 2021-129972

(51) Int. Cl. H01L 27/146

(52) U.S. Cl. CPC H01L 27/14614; H01L 27/1463; H01L 27/14634; H01L 27/1464; H01L 27/14645; H01L 27/14689

(57) ABSTRACT

Provided is a photodetector that can suppress a decrease in saturation charge accumulation amount. The photodetector includes a first semiconductor layer that includes a photoelectric conversion section and that has one surface serving as a light incident surface and another surface serving as a first surface, a second semiconductor layer that is stacked on the first surface and that includes a charge accumulation region, and a gate electrode that is adjacent to the second semiconductor layer through an insulating film and that allows formation of a channel extending in a stacking direction of the first semiconductor layer and the second semiconductor layer, between the photoelectric conversion section and the charge accumulation region.

### TECHNICAL FIELD

The present technology (the technology according to the present disclosure) relates to a photodetector, a method of manufacturing a photodetector, and an electronic apparatus, in particular, to a photodetector having a charge accumulation region, a method of manufacturing a photodetector, and an electronic apparatus.

### BACKGROUND ART

In order to control the timing of signal charge readout on a pixel-by-pixel basis, an image sensor may temporarily accumulate signal charges obtained through photoelectric conversion by a photo diode (PD) in a charge accumulation region such as a floating diffusion (FD) region, through a transfer channel having a transfer gate (TG).

Besides, various innovations have been proposed regarding a transfer path of signal charges from a PD to an FD region. For example, in PTL 1, the width of a TG in plan view of an image sensor is expanded in a direction from a PD toward an FD region, thereby concentrating a transfer path toward the FD region. Further, in PTL 2, a TG is formed using a Fin-type transistor, thereby expanding a transfer path toward a silicon substrate side.

### CITATION LIST

### Patent Literature

PTL 1: Japanese Patent Laid-open No. 2020-17753

PTL 2: Japanese Patent Laid-open No. 2017-27982

### SUMMARY

### Technical Problem

In general image sensors as described above, an FD region and a transfer channel are formed within the same semiconductor substrate as a PD. Hence, the volume of the PD is reduced, leading to a decrease in saturation charge accumulation amount inside a pixel due to pixel miniaturization in some cases.

It is an object of the present technology to provide a photodetector that can suppress a decrease in saturation charge accumulation amount, a method of manufacturing a photodetector, and an electronic apparatus.

### Solution to Problem

A photodetector according to an aspect of the present technology includes a first semiconductor layer that includes a photoelectric conversion section and that has one surface serving as a light incident surface and another surface serving as a first surface, a second semiconductor layer that is stacked on the first surface and that includes a charge accumulation region, and a gate electrode that is adjacent to the second semiconductor layer through an insulating film and that allows formation of a channel extending in a stacking direction of the first semiconductor layer and the second semiconductor layer, between the photoelectric conversion section and the charge accumulation region.

A method of manufacturing a photodetector according to an aspect of the present technology includes preparing a first semiconductor layer, stacking a second semiconductor layer on a first surface that is a surface on a side opposite to a side of a light incident surface of the first semiconductor layer, partitioning the second semiconductor layer into island-shaped portions in plan view, and forming a gate electrode in a region adjacent to the second semiconductor layer through an insulating film, the gate electrode allowing formation of a channel extending in a stacking direction of the first semiconductor layer and the second semiconductor layer, between a photoelectric conversion section provided in the first semiconductor layer and a charge accumulation region provided in the second semiconductor layer.

An electronic apparatus according to an aspect of the present technology includes the above-mentioned photodetector and an optical system configured to form an image of image light from an object on the above-mentioned photodetector.

### BRIEF DESCRIPTION OF DRAWINGS

FIG. 1 is a chip layout diagram illustrating a configuration example of a photodetector according to a first embodiment of the present technology.

FIG. 2 is a block diagram illustrating a configuration example of the photodetector according to the first embodiment of the present technology.

FIG. 3 is an equivalent circuit diagram of a pixel of the photodetector according to the first embodiment of the present technology.

FIG. 4A is a longitudinal sectional view of the photodetector according to the first embodiment of the present technology.

FIG. 4B is a transverse sectional view illustrating a cross-section of the photodetector when viewed in cross-section along a cutting line A-A of FIG. 4A.

FIG. 4C is a transverse sectional view illustrating a cross-section of the photodetector when viewed in cross-section along a cutting line B-B of FIG. 4A.

FIG. 5 is a process sectional view illustrating a method of manufacturing the photodetector according to the first embodiment of the present technology.

FIG. 6 is a process sectional view following FIG. 5.

FIG. 7A is a process sectional view illustrating a transverse section, following FIG. 6.

FIG. 7B is a process sectional view illustrating a longitudinal section, following FIG. 6.

FIG. 8A is a process sectional view illustrating a transverse section, following FIG. 7A.

FIG. 8B is a process sectional view illustrating a longitudinal section, following FIG. 7B.

FIG. 9 is a process sectional view following FIG. 8B.

FIG. 10 is a process sectional view following FIG. 9.

FIG. 11 is a process sectional view following FIG. 10.

FIG. 12 is a process sectional view following FIG. 11.

FIG. 13 is a process sectional view following FIG. 12.

FIG. 14 is a process sectional view following FIG. 13.

FIG. 15 is a longitudinal sectional view of a photodetector according to a comparative example.

FIG. 16A is a longitudinal sectional view of a photodetector according to Modified Example 2 of the first embodiment of the present technology.

FIG. 16B is a transverse sectional view illustrating a cross-section of the photodetector when viewed in cross-section along a cutting line B-B of FIG. 16A.

FIG. 17A is a longitudinal sectional view of a photodetector according to Modified Example 3 of the first embodiment of the present technology.

FIG. 17B is a transverse sectional view illustrating a cross-section of the photodetector when viewed in cross-section along a cutting line A-A of FIG. 17A.

FIG. 17C is a transverse sectional view illustrating a cross-section of the photodetector when viewed in cross-section along a cutting line B-B of FIG. 17A.

FIG. 18A is a longitudinal sectional view of a photodetector according to Modified Example 4 of the first embodiment of the present technology.

FIG. 18B is a transverse sectional view illustrating a cross-section of the photodetector when viewed in cross-section along a cutting line A-A of FIG. 18A.

FIG. 19A is a process sectional view illustrating a method of manufacturing a photodetector according to Modified Example 5 of the first embodiment of the present technology.

FIG. 19B is a process sectional view following FIG. 19A.

FIG. 20 is a longitudinal sectional view of a photodetector according to Example 1 of a second embodiment of the present technology.

FIG. 21 is a longitudinal sectional view of a photodetector according to Example 2 of the second embodiment of the present technology.

FIG. 22 is a longitudinal sectional view of a photodetector according to Example 3 of the second embodiment of the present technology.

FIG. 23 is a longitudinal sectional view of a photodetector according to Example 4 of the second embodiment of the present technology.

FIG. 24 is a longitudinal sectional view of a photodetector according to a third embodiment of the present technology.

FIG. 25 is a longitudinal sectional view of a photodetector according to a fourth embodiment of the present technology.

FIG. 26 is a diagram illustrating a schematic configuration of an electronic apparatus according to a fifth embodiment of the present technology.

### DESCRIPTION OF EMBODIMENTS

Now, preferred modes for carrying out the present technology are described with reference to the drawings. Note that embodiments described below represent examples of representative embodiments of the present technology, and the scope of the present technology should not narrowly be interpreted on the basis of these.

In the illustration of the drawings referred to below, identical or similar portions are denoted by identical or similar reference signs. However, it should be noted that the drawings are schematic, and hence, relations between thicknesses and planar dimensions, ratios of thicknesses of respective layers, and the like are different from the actual ones. Therefore, specific thicknesses and dimensions should be determined with reference to the following description. Further, needless to say, the drawings are sometimes different from each other in dimensional relation or ratio.

Further, the embodiments described below exemplify devices and methods for embodying the technical ideas of the present technology, and the technical ideas of the present technology are not specific to the following in terms of materials, shapes, structures, arrangement, and the like of components. The technical ideas of the present technology can be modified in various ways within the technical scope defined by the claims described in CLAIMS.

Descriptions are given in the following order.
1. First Embodiment
2. Second Embodiment
3. Third Embodiment
4. Fourth Embodiment
5. Fifth Embodiment

### First Embodiment

In the first embodiment, an example of applying the present technology to a photodetector, which is a back-illuminated CMOS (Complementary Metal Oxide Semiconductor) image sensor, is described.

### Overall Configuration of Photodetector

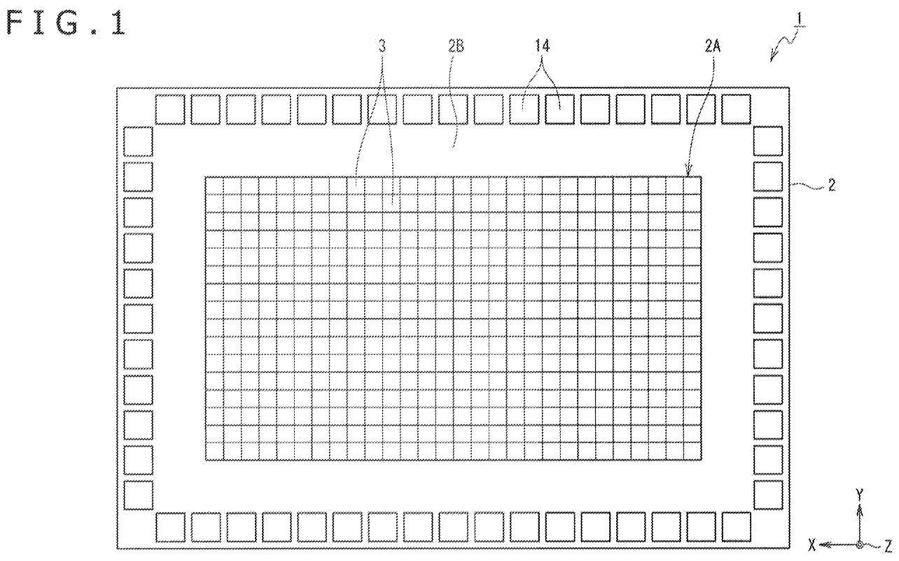

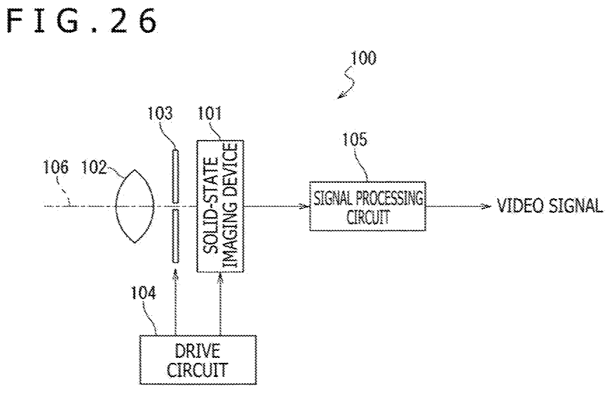

First, an overall configuration of a photodetector 1 is described. As illustrated in FIG. 1, the photodetector 1 according to the first embodiment of the present technology primarily includes a semiconductor chip 2 with a rectangular two-dimensional planar shape when viewed in plan view. That is, the photodetector 1 is mounted on the semiconductor chip 2. As illustrated in FIG. 26, the photodetector 1 captures image light (incident light 106) from an object through an optical system (optical lens) 102, converts the light amount of the incident light 106, an image of which has been formed on an imaging surface, into electrical signals on a pixel-by-pixel basis, and outputs the electrical signals as pixel signals.

As illustrated in FIG. 1, the semiconductor chip 2 having mounted thereon the photodetector 1 includes, in a two-dimensional plane including an X direction and a Y direction that intersect each other, a rectangular pixel region 2A provided at a central part, and a peripheral region 2B provided outside the pixel region 2A to surround the pixel region 2A.

The pixel region 2A is a light-receiving surface for receiving light condensed by the optical system 102 illustrated in FIG. 26, for example. Besides, in the pixel region 2A, multiple pixels 3 are arranged in a matrix in the two-dimensional plane including the X direction and the Y direction. In other words, the pixels 3 are repeatedly arranged in each of the X direction and the Y direction that intersect each other in the two-dimensional plane. Note that, in the present embodiment, as an example, the X direction is orthogonal to the Y direction. Further, a direction orthogonal to both the X direction and the Y direction is a Z direction (a thickness direction or stacking direction of the photodetector 1 and each layer thereof).

As illustrated in FIG. 1, multiple bonding pads 14 are arranged in the peripheral region 2B. The respective bonding pads 14 are arrayed along four respective sides in the two-dimensional plane of the semiconductor chip 2. Each of the multiple bonding pads 14 is an input/output terminal used when the semiconductor chip 2 is electrically connected to an external device.

### Logic Circuit

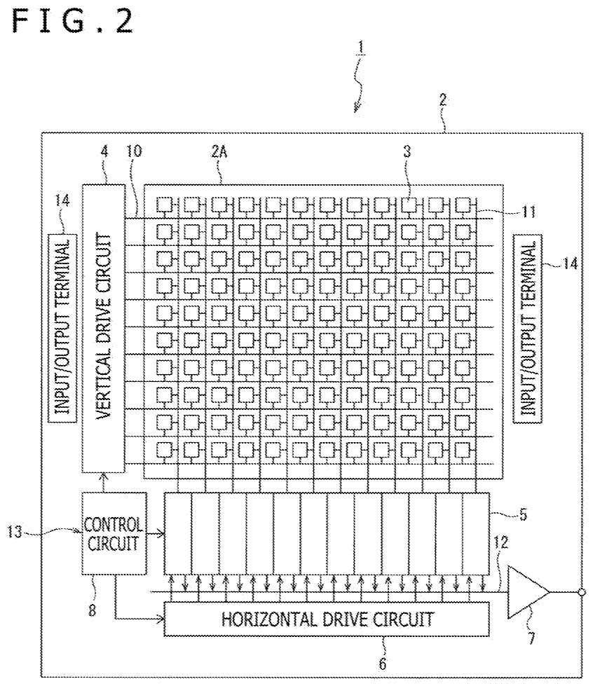

As illustrated in FIG. 2, the semiconductor chip 2 includes a logic circuit 13 including a vertical drive circuit 4, column signal processing circuits 5, a horizontal drive circuit 6, an output circuit 7, a control circuit 8, and the like. The logic circuit 13 includes a CMOS (Complementary MOS) circuit including, for example, an n-channel conductivity type MOSFET (Metal Oxide Semiconductor Field Effect Transistor) and a p-channel conductivity type MOSFET as field effect transistors.

The vertical drive circuit 4 includes, for example, a shift register. The vertical drive circuit 4 sequentially selects desired pixel drive lines 10, supplies pulses for driving the pixels 3 to the selected pixel drive line 10, and drives each of the pixels 3 on a row-by-row basis. That is, the vertical drive circuit 4 sequentially selects and scans the respective pixels 3 in the pixel region 2A in the vertical direction on a row-by-row basis and supplies pixel signals from the pixels 3 based on signal charges generated by photoelectric conversion elements of the respective pixels 3 in response to the amount of received light to the column signal processing circuits 5 through vertical signal lines 11.

The column signal processing circuit 5 is disposed for each column of the pixels 3, for example, and performs, for each pixel column, signal processing such as noise removal on signals output from the pixels 3 in the single row. For example, the column signal processing circuit 5 performs signal processing such as CDS (Correlated Double Sampling) and AD (Analog Digital) conversion for removing pixel-specific fixed pattern noise. A horizontal selection switch (not illustrated) is connected between an output stage of the column signal processing circuit 5 and the horizontal signal line 12.

The horizontal drive circuit 6 includes, for example, a shift register. By sequentially outputting horizontal scan pulses to the column signal processing circuits 5, the horizontal drive circuit 6 sequentially selects the respective column signal processing circuits 5 and causes the respective column signal processing circuits 5 to output pixel signals subjected to signal processing to the horizontal signal line 12.

The output circuit 7 performs signal processing on pixel signals sequentially supplied from the respective column signal processing circuits 5 through the horizontal signal line 12 and outputs the resultant. As the signal processing, for example, buffering, black level adjustment, column variation correction, or other various types of digital signal processing can be used.

The control circuit 8 generates clock signals and control signals serving as references for operation of the vertical drive circuit 4, the column signal processing circuits 5, the horizontal drive circuit 6, and the like, on the basis of vertical synchronization signals, horizontal synchronization signals, and master clock signals. Then, the control circuit 8 outputs the generated clock signals and control signals to the vertical drive circuit 4, the column signal processing circuits 5, the horizontal drive circuit 6, and the like.

### Pixel

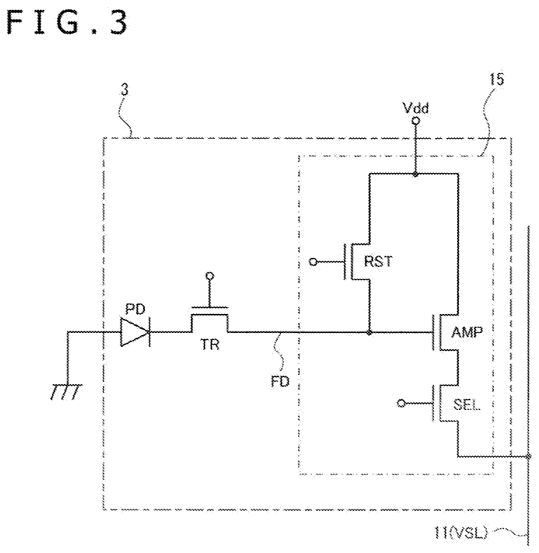

FIG. 3 is an equivalent circuit diagram illustrating a configuration example of the pixel 3. The pixel 3 includes a photoelectric conversion element PD, a charge accumulation region FD for accumulating (holding) signal charges generated through photoelectric conversion by the photoelectric conversion element PD, and a transfer transistor TR configured to transfer signal charges generated through photoelectric conversion by the photoelectric conversion element PD to the charge accumulation region FD. Further, the pixel 3 includes a readout circuit 15 electrically connected to the charge accumulation region FD.

The photoelectric conversion element PD generates signal charges corresponding to the amount of received light. Further, the photoelectric conversion element PD temporarily accumulates (holds) the generated signal charges. A cathode side of the photoelectric conversion element PD is electrically connected to a source region of the transfer transistor TR, and an anode side thereof is electrically connected to a reference potential line (for example, ground). A photodiode is used as the photoelectric conversion element PD, for example.

A drain region of the transfer transistor TR is electrically connected to the charge accumulation region FD. A gate electrode of the transfer transistor TR is electrically connected to a transfer transistor drive line among the pixel drive lines 10 (see FIG. 2).

The charge accumulation region FD temporarily accumulates and holds signal charges transferred from the photoelectric conversion element PD through the transfer transistor TR.

The readout circuit 15 reads out signal charges accumulated in the charge accumulation region FD and outputs pixel signals based on the signal charges. The readout circuit 15 includes, but is not limited to, an amplification transistor AMP, a selection transistor SEL, and a reset transistor RST, for example, as pixel transistors. These transistors (AMP, SEL, and RST) include MOSFETs including, for example, a gate insulating film including a silicon oxide film (SiO₂ film), a gate electrode, and a pair of main electrode regions functioning as a source region and a drain region. Further, these transistors may be MISFETs (Metal Insulator Semiconductor FETs) in which a gate insulating film includes a silicon nitride film (Si₃N₄ film) or a stacked film including a silicon nitride film, a silicon oxide film, and the like.

A source region of the amplification transistor AMP is electrically connected to a drain region of the selection transistor SEL, and a drain region thereof is electrically connected to a power supply line Vdd and a drain region of the reset transistor. Besides, a gate electrode of the amplification transistor AMP is electrically connected to the charge accumulation region FD and a source region of the reset transistor RST.

A source region of the selection transistor SEL is electrically connected to the vertical signal line 11 (VSL), and the drain region thereof is electrically connected to the source region of the amplification transistor AMP. Besides, a gate electrode of the selection transistor SEL is electrically connected to a selection transistor drive line among the pixel drive lines 10 (see FIG. 2).

The source region of the reset transistor RST is electrically connected to the charge accumulation region FD and the gate electrode of the amplification transistor AMP, and the drain region thereof is electrically connected to the power supply line Vdd and the drain region of the amplification transistor AMP. A gate electrode of the reset transistor RST is electrically connected to a reset transistor drive line among the pixel drive lines 10 (see FIG. 2).

### Specific Configuration of Photodetector

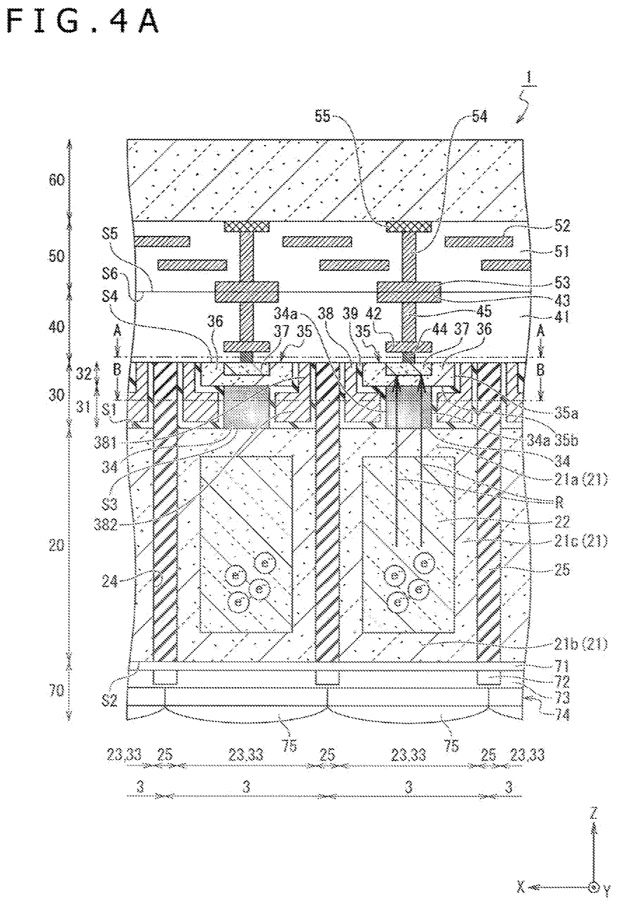

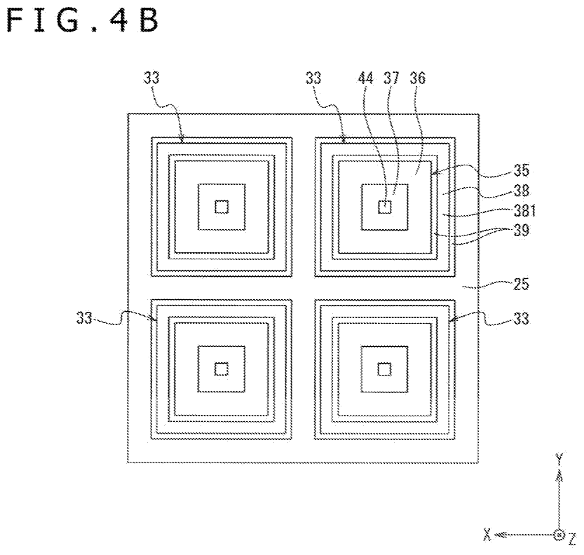

Next, a specific configuration of the photodetector 1 is described using FIG. 4A, FIG. 4B, and FIG. 4C.

### Stacked Structure of Photodetector

As illustrated in FIG. 4A, the photodetector 1 (semiconductor chip 2) includes a first semiconductor layer 20, a second semiconductor layer 30, a first wiring layer 40, a second wiring layer 50, and a third semiconductor layer 60. The first semiconductor layer 20 includes a photoelectric conversion section described later and has a first surface S1 and a second surface S2 located on opposite sides. The second semiconductor layer 30 has a third surface S3 and a fourth surface S4 located on opposite sides. The second semiconductor layer 30 is stacked on the first surface S1 and includes a charge accumulation region described later. The first wiring layer 40 is overlaid on the surface (fourth surface S4) on the opposite side to the surface (third surface S3) on the first semiconductor layer 20 side of the second semiconductor layer 30. The second wiring layer 50 is overlaid on a surface (fifth surface S5) on an opposite side to a surface on the second semiconductor layer 30 side of the first wiring layer 40. The third semiconductor layer 60 is overlaid on a surface on an opposite side to a surface (sixth surface S6) on the first wiring layer 40 side of the second wiring layer 50. Such a stacked structure can be achieved, for example, by stacking the second semiconductor layer 30 and the first wiring layer 40 on the first semiconductor layer 20 and stacking the second wiring layer 50 on the third semiconductor layer 60, and then overlaying and bonding the fifth surface S5 of the first wiring layer 40 with the sixth surface S6 of the second wiring layer 50.

Here, the second surface S2, which is one surface of the first semiconductor layer 20, is sometimes referred to as a light incident surface or a back surface, and the other surface of the first semiconductor layer 20, that is, the first surface S1, which is the surface on the opposite side to the second surface S2, is sometimes referred to as an element formation surface or a main surface. Moreover, the photodetector 1 (semiconductor chip 2) includes a condensing layer 70 stacked on the second surface S2.

### Condensing Layer

The condensing layer 70 has, but is not limited to, a stacked structure including an insulating layer 71, a light-blocking layer 72, a planarization film 73, a color filter 74, and an on-chip lens 75 stacked in this order from the second surface S2 side, for example.

### Insulating Layer

The insulating layer 71 is an insulating film stacked on the second surface S2 side of the first semiconductor layer 20 by the CVD (Chemical Vapor Deposition) method, for example. The insulating layer 71 can include, but is not limited to, a material such as silicon oxide (SiO₂).

### Light-Blocking Layer

The light-blocking layer 72 is stacked on the insulating layer 71. The light-blocking layer 72 is disposed in a boundary region of the pixel 3 and blocks stray light leaking from adjacent pixels. The light-blocking layer 72 is only required to include a material that blocks light, and may include, as a material that has strong light-blocking properties and that can precisely be processed through fine processing such as etching, a metal film of aluminum (Al), tungsten (W), or copper (Cu), for example.

### Planarization Film

The planarization film 73 is provided to cover the insulating layer 71 and the light-blocking layer 72, thereby flattening the surface on which the color filter 74 is provided.

### Color Filter

The color filter 74 separates by colors incident light that has entered from the light incident surface side of the photodetector 1 and passed through the on-chip lens 75, for example, and supplies the incident light obtained after color separation to the pixel 3. The color filter 74 includes, but is not limited to, multiple types of filters configured to separate different colors such as red, blue, and green. Besides, the color filter 74 supplies light of different colors to different pixels.

### On-Chip Lens

The on-chip lens 75 has a function of condensing incident light to a photoelectric conversion section 22. The on-chip lens 75 is disposed for each of the pixels 3. The on-chip lens 75 can include, but is not limited to, an organic material, examples of which include styrene-based resin, acrylic-based resin, styrene-acrylic-based resin, and siloxane-based resin.

### First Semiconductor Layer

The first semiconductor layer 20 includes a single-crystal silicon substrate. As illustrated in FIG. 4A, the first semiconductor layer 20 includes a semiconductor region 21 of a first conductivity type, for example, the p-type, and a semiconductor region 22 of a second conductivity type, for example, the n-type, embedded in the semiconductor region 21.

### Photoelectric Conversion Region

The first semiconductor layer 20 includes island-shaped photoelectric conversion regions 23 partitioned by separation regions 25. That is, the photoelectric conversion regions 23 are separated from each other by the separation regions 25. Further, a semiconductor region 21c of a conductivity type different from that of the semiconductor region 22, for example, the p-type, is provided between the semiconductor region 22 and the separation region 25. The photoelectric conversion region 23 is provided for each of the pixels 3. The number of pixels 3 is not limited to the one illustrated in the figure.

The photoelectric conversion region 23 includes the semiconductor region 21 and the semiconductor region 22 described above. When receiving light, the semiconductor region 22 performs photoelectric conversion on the incident light to generate signal charges. This semiconductor region 22 is hereinafter referred to as the photoelectric conversion section 22. The photoelectric conversion element PD illustrated in FIG. 3 is configured in a region including the semiconductor region 21 and the photoelectric conversion section 22 illustrated in FIG. 4A. Further, the photoelectric conversion section 22 illustrated in FIG. 4A functions as the source region of the transfer transistor TR illustrated in FIG. 3.

### Separation Region

The separation region 25 has a trench structure obtained by forming a groove 24 in the first semiconductor layer 20 and the second semiconductor layer 30 and filling the groove 24 with a material such as an insulating material. Further, the separation region 25 is provided to penetrate from the fourth surface S4 of the second semiconductor layer 30 to the second surface S2 of the first semiconductor layer 20. That is, the separation region 25 has an FTI (Full Trench Isolation) structure.

### Second Semiconductor Layer

As illustrated in FIG. 4A, the second semiconductor layer 30 is a semiconductor layer stacked on the first surface S1. The second semiconductor layer 30 has a stacked structure in which a first layer 31 and a second layer 32 are stacked in this order from the first surface S1. The first layer 31 is a silicon germanium (SiGe) layer epitaxially grown on the first surface S1 and is a semiconductor region of the first conductivity type, for example, the p-type. The second layer 32 is a silicon (Si) layer epitaxially grown on a surface on an opposite side to the first semiconductor layer 20 side of the first layer 31.

### Element Formation Region

The second semiconductor layer 30 includes island-shaped element formation regions 33 partitioned by the separation regions 25. The element formation region 33 is provided for each of the pixels 3. Besides, the element formation region 33 includes the first layer 31 and the second layer 32 described above. More specifically, the element formation region 33 includes a channel section 34 including the first layer 31 and an accumulation section 35 including the second layer 32. Further, the element formation region 33 is provided with a transfer gate electrode 38.

### Accumulation Section

The accumulation section 35 includes a semiconductor region 36 of the first conductivity type, for example, the p-type, and a semiconductor region 37 of the second conductivity type, for example, the n-type. The semiconductor region 37 exhibits the same conductivity type as the photoelectric conversion section 22, that is, the second conductivity type. The semiconductor region 37 is a floating diffusion region for temporarily accumulating signal charges transferred from the photoelectric conversion section 22. This semiconductor region 37 is hereinafter referred to as a charge accumulation region 37. The charge accumulation region 37 illustrated in FIG. 4A functions as the drain region of the transfer transistor TR illustrated in FIG. 3.

The element formation region 33 of the second semiconductor layer 30 includes the channel section 34 and the accumulation section 35 provided in this order from the first semiconductor layer 20 side as described above. That is, the element formation region 33 has a stacked structure in which the channel section 34 and the accumulation section 35 are stacked in this order from the first semiconductor layer 20 side. The charge accumulation region 37 is provided only in the accumulation section 35 among the channel section 34 and the accumulation section 35. That is, the charge accumulation region 37 is provided at a position closer to the surface on the opposite side to the first semiconductor layer 20 side of the second semiconductor layer 30.

The charge accumulation region 37 is surrounded by the semiconductor region 36 of the conductivity type different from that of the charge accumulation region 37. The charge accumulation region 37 is surrounded by the semiconductor region 36, thereby preventing inflow of noise into the charge accumulation region 37. Moreover, the semiconductor region 36 is interposed between the charge accumulation region 37 and the channel section 34. Further, a portion of the charge accumulation region 37 faces the fourth surface S4.

### Channel Section

As illustrated in FIG. 4A, the channel section 34 is provided between the accumulation section 35 and the first semiconductor layer 20 in the Z direction. As illustrated in FIG. 4C, in plan view, the channel section 34 is located inside the accumulation section 35. That is, in plan view, the channel section 34 has a diameter smaller than that of the accumulation section 35. Note that “diameter” refers to a distance between side surfaces and that the planar shapes of the channel section 34 and the accumulation section 35 are not limited to any shape.

The channel section 34 illustrated in FIG. 4A can function as a channel of the transfer transistor TR illustrated in FIG. 3. More specifically, the channel section 34 is modulated by the transfer gate electrode 38, which is described later, from a side surface 34a side. Here, the side surface 34a of the channel section 34 is a surface facing in a direction intersecting the stacking direction (Z direction).

### Transfer Gate Electrode

The transfer gate electrode 38 illustrated in FIG. 4A functions as the gate electrode of the transfer transistor TR illustrated in FIG. 3. The transfer gate electrode 38 is adjacent to the channel section 34, the accumulation section 35, and the first surface S1 of the first semiconductor layer 20 through an insulating film 39 functioning as a gate insulating film of the transfer transistor TR. The transfer gate electrode 38 is a gate electrode that extends along the thickness direction of the second semiconductor layer 30 and allows formation of a channel extending in the stacking direction (thickness direction) of the first semiconductor layer 20 and the second semiconductor layer 30, between the photoelectric conversion section 22 and the charge accumulation region 37.

Further, the transfer gate electrode 38 includes a first section 381 adjacent to a side surface 35a of the accumulation section 35 through the insulating film 39 and a second section 382 adjacent to the side surface 34a of the channel section 34 through the insulating film 39. The second section 382 has an inner diameter smaller than that of the first section 381. Note that “inner diameter” refers to a distance between inner peripheral surfaces across the center and that the planar shape of the transfer gate electrode 38 is not limited to any shape.

The transfer transistor TR transfers signal charges obtained through photoelectric conversion by the photoelectric conversion section 22 to the charge accumulation region 37. More specifically, the transfer transistor TR modulates the potential of the semiconductor region in response to the voltage between the gate and the source to form a channel. More specifically, the transfer transistor TR modulates the potential of the semiconductor region extending over the semiconductor region 21, the channel section 34, and the semiconductor region 36 of the accumulation section 35 to form a channel. With this, the transfer transistor TR transfers signal charges from the photoelectric conversion section 22 functioning as a source region to the charge accumulation region 37 functioning as a drain region through the channel.

Further, as illustrated in FIG. 4B and FIG. 4C, the transfer gate electrode 38 surrounds the element formation region 33 of the second semiconductor layer 30 entirely in a circumferential direction in plan view. The transfer gate electrode 38 modulates the element formation region 33 from the side surface side. More specifically, the transfer gate electrode 38 surrounds the accumulation section 35 and the channel section 34 in plan view and is adjacent to the side surface 35a of the accumulation section 35, a bottom surface 35b of the accumulation section 35, the side surface 34a of the channel section 34, and the first surface S1 through the insulating film 39. The transfer gate electrode 38 modulates the potential of the semiconductor region through these surfaces in response to the voltage between the gate and the source.

The channel section 34 is modulated entirely in the circumferential direction through the side surface 34a, and hence, a wider region is modulated compared to a case where the channel section 34 is not surrounded. Moreover, the channel section 34 is etched from the side surface 34a side to be reduced in diameter. With this, the channel section 34 is modulated up to, for example, near the center, more preferably, up to the center, although this is not limitative. The channel section 34 is modulated by the transfer gate electrode 38 along the direction vertical to the Z direction.

The transfer gate electrode 38 is formed using metal such as aluminum (Al) or copper (Cu), or a material such as polysilicon (Poly-Si), for example. It is assumed here that the transfer gate electrode 38 includes aluminum (Al), although this is not limitative.

### First Wiring Layer

As illustrated in FIG. 4A, the first wiring layer 40 includes an interlayer insulating film 41, a metal layer 42, a first connection pad 43, a contact 44, and a via 45. The metal layer 42 and the first connection pad 43 are stacked through the interlayer insulating film 41 as illustrated in the figure. The contact 44 is connected at one end thereof in the Z direction to the charge accumulation region 37. The other end in the Z direction of the contact 44 may be connected to the metal layer 42. The via 45 connects the metal layer 42 to another metal layer 42 and the first connection pad 43. The first connection pad 43 faces the fifth surface S5 of the first wiring layer 40.

### Second Wiring Layer

The second wiring layer 50 includes an interlayer insulating film 51, a metal layer 52, a second connection pad 53, and a via 54. The metal layer 52 and the second connection pad 53 are stacked through the interlayer insulating film 51 as illustrated in the figure. The via 54 connects the metal layer 52 to another metal layer 52 and the second connection pad 53. The second connection pad 53 faces the sixth surface S6 of the second wiring layer 50 and is bonded with the first connection pad 43. With this, the metal layers of the first wiring layer 40 and the second wiring layer 50 are electrically connected to each other. Further, the second wiring layer 50 may be provided with a gate electrode 55 of a transistor provided in the third semiconductor layer 60.

### Third Semiconductor Layer

The third semiconductor layer 60 includes, but is not limited to, a single-crystal silicon substrate, for example. The third semiconductor layer 60 is provided with the pixel transistors of the readout circuit 15. Further, the third semiconductor layer 60 may be provided with the transistors forming the logic circuit 13, although this is not limitative. Here, a description is given on the assumption that these transistors are provided at positions closer to the second wiring layer 50 side of the third semiconductor layer 60, although this is not limitative.

### Action

Now, the action of the photodetector 1 is described. When the on-chip lens 75 side of the photodetector 1 is irradiated with light, photoelectric conversion is performed by the photoelectric conversion section 22 to generate signal charges. After that, when the transfer transistor TR is turned on, the potential of the semiconductor region between the photoelectric conversion section 22 and the charge accumulation region 37, that is, the potentials of the semiconductor region 21a, the channel section 34, and the semiconductor region 36, are modulated to form a channel extending in the Z direction. Then, the signal charges are transferred from the photoelectric conversion section 22 to the charge accumulation region 37 through the formed channel. At this time, as illustrated in FIG. 4A, a transfer path R for electrons extends from the photoelectric conversion section 22 to the charge accumulation region 37 along the extending direction of the transfer gate electrode 38, that is, the Z direction. Further, the charge accumulation region 37 is connected to the contact 44, and the signal charges are transferred to the next stage through the contact 44.

In the photodetector 1, the charge accumulation regions 37 are electrically separated from each other. Besides, as illustrated in FIG. 3, the single charge accumulation region 37 is connected to the single readout circuit 15, and signal charges are independently read out from the respective charge accumulation regions 37. Therefore, regarding the transfer of signal charges, all the channel sections 34 may simultaneously be modulated (global shutter operation) or the channel sections 34 may sequentially be modulated (rolling shutter operation).

### Method of Manufacturing Photodetector

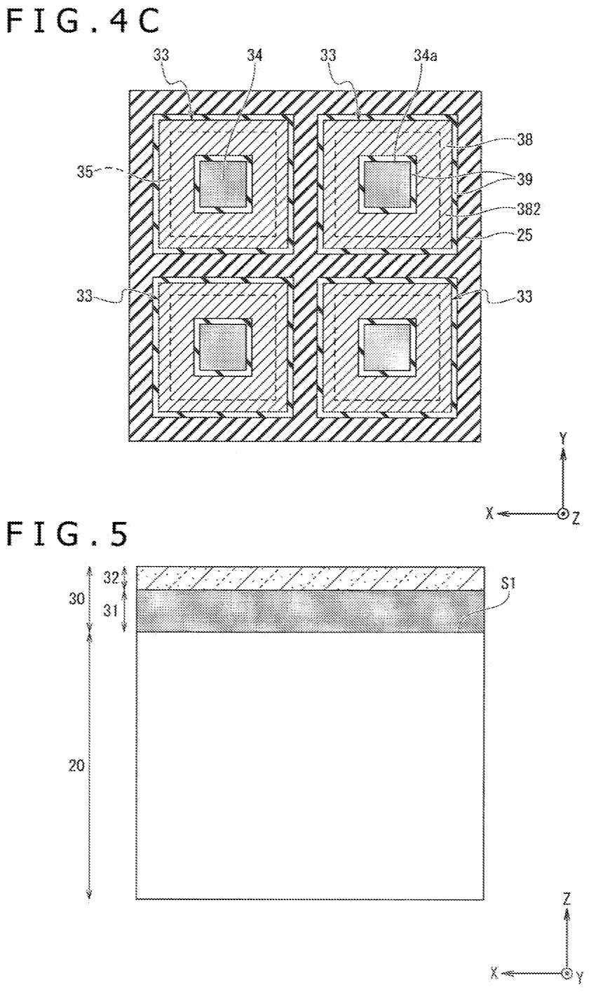

Now, a method of manufacturing the photodetector 1 is described with reference to FIG. 5 to FIG. 14. First, as illustrated in FIG. 5, the first semiconductor layer 20 including silicon is prepared, and the second semiconductor layer 30 is stacked on the first surface S1, which is the surface on the opposite side to the light incident surface side of the first semiconductor layer 20, by epitaxial growth. More specifically, the first layer 31 and the second layer 32, which serve as the second semiconductor layer 30, are stacked in this order on the first surface S1 by epitaxial growth. At this time, the first layer 31 and the second layer 32 are stacked in a crystalline state. Note that, when the first layer 31 and the second layer 32 are stacked, the respective layers are doped with impurities and stacked. More specifically, silicon germanium exhibiting the p-type is deposited on the first surface S1 as the first layer 31. Then, as the second layer 32, silicon exhibiting the p-type is deposited on the first layer 31, that is, on the surface on the opposite side to the first semiconductor layer 20 of the first layer 31.

Here, in general, in a case where materials with different lattice structures are stacked on each other, in order to suppress occurrence of stacking defects, it is necessary to make the film thickness smaller than a critical film thickness (a film thickness at which stacking defects occur). Here, the two types of materials, namely, silicon and silicon germanium, are used, and it is necessary to form a silicon germanium film with a thickness smaller than the critical film thickness. Here, a case where the content of germanium in silicon germanium is 10 percent (Si_{0.9}Ge_{0.1}) is considered, for example, although the present technology is not limited to this. In that case, since the critical film thickness of silicon germanium is approximately 30 nm, it is sufficient to form a silicon germanium film with a thickness smaller than 30 nm.

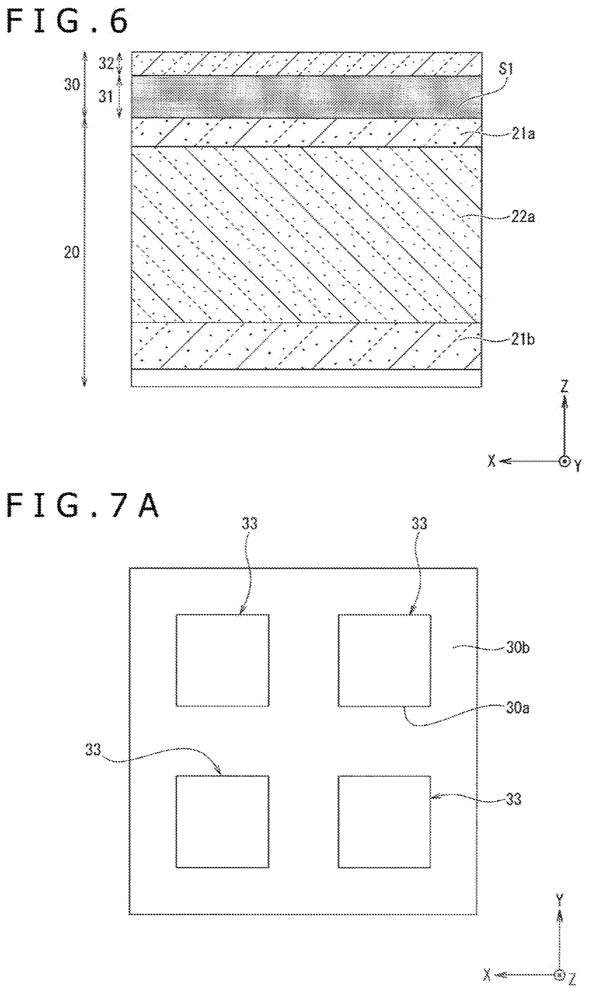

Next, as illustrated in FIG. 6, impurities are injected into the first semiconductor layer 20 to form p-type semiconductor regions 21a and 21b and an n-type semiconductor region 22a. These semiconductor regions are formed from the first surface S1 side along the Z direction in the order of the semiconductor region 21a, the semiconductor region 22a, and the semiconductor region 21b.

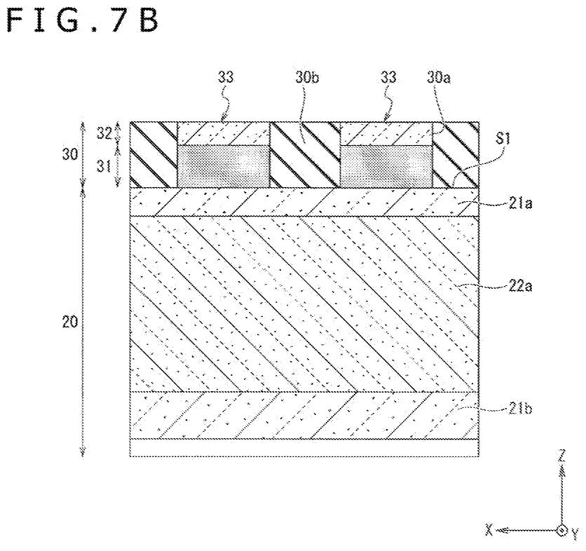

After that, as illustrated in FIG. 7A and FIG. 7B, using known lithography and etching techniques, a lattice-shaped groove 30a recessed in the Z direction is formed in the second semiconductor layer 30. The groove 30a penetrates the second semiconductor layer 30 in the thickness direction, more specifically, extends to the interface between the first layer 31 and the first semiconductor layer 20. Besides, with this, the second semiconductor layer 30 is partitioned into the island-shaped element formation regions 33 in plan view. Then, the groove 30a is filled with a sacrificial layer 30b. The material of the sacrificial layer 30b has etching selectivity with respect to the materials of the first semiconductor layer 20, the second semiconductor layer 30, and the separation region 25. That is, the material of the sacrificial layer 30b has a higher etching rate than that of the material of the separation region 25. Further, unnecessary portions of the sacrificial layer 30b may be removed by known etch back techniques.

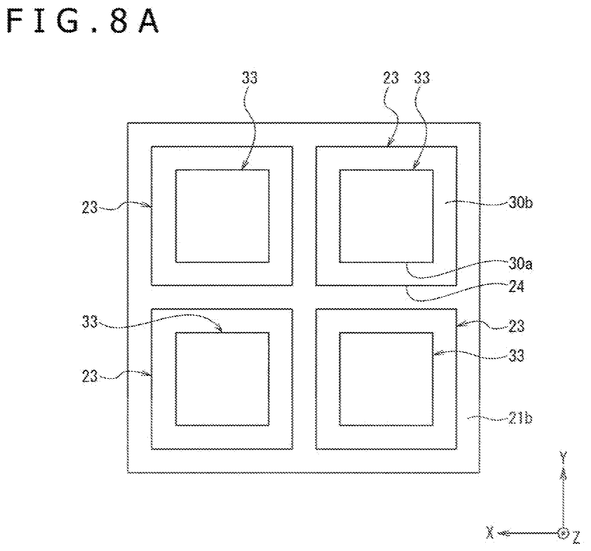

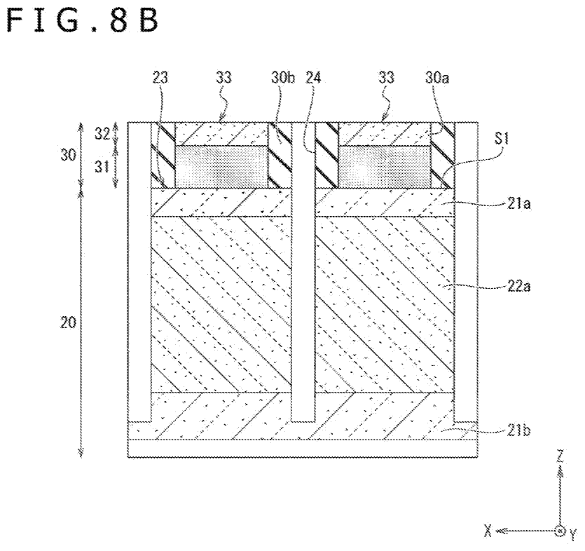

Then, as illustrated in FIG. 8A and FIG. 8B, using known lithography and etching techniques, the lattice-shaped groove 24 recessed in the Z direction is formed in the region in which the sacrificial layer 30b has been provided. The groove 24 penetrates the sacrificial layer 30b in the thickness direction and extends into the semiconductor region 21b of the first semiconductor layer 20. With this, the first semiconductor layer 20 is partitioned into the island-shaped photoelectric conversion regions 23 in plan view.

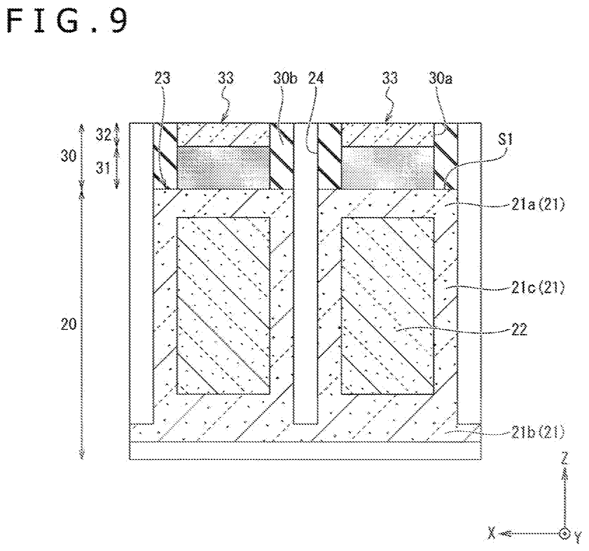

Next, as illustrated in FIG. 9, impurities are introduced into sidewalls of the groove 24, using known plasma doping techniques. With this, the p-type semiconductor region 21c is formed along the sidewalls of the groove 24. The semiconductor region 21c functions as a pinning layer. Besides, the p-type semiconductor region 21 includes these semiconductor regions 21a, 21b, and 21c. Further, the remaining portion of the semiconductor region 22a surrounded by the semiconductor region 21 corresponds to the n-type semiconductor region 22.

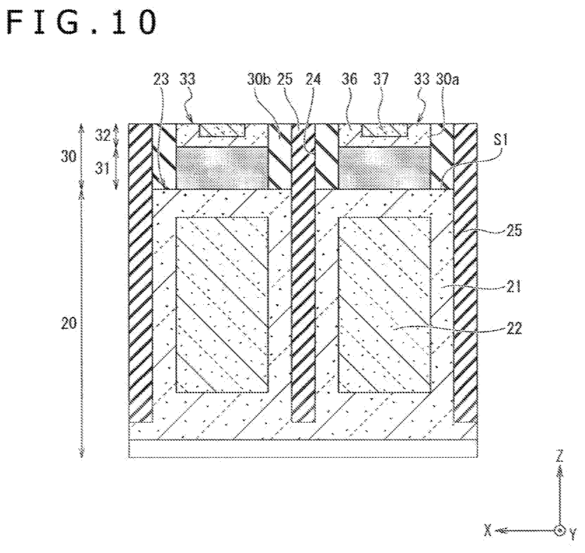

Then, as illustrated in FIG. 10, the groove 24 is filled with a material such as an insulating material to form the separation region 25. Moreover, using known lithography and ion implantation techniques, impurities are injected into the second layer 32 of the element formation region 33 to form an n-type semiconductor region, that is, the charge accumulation region 37. Besides, the remaining portion of the second layer 32 as a p-type semiconductor region corresponds to the semiconductor region 36.

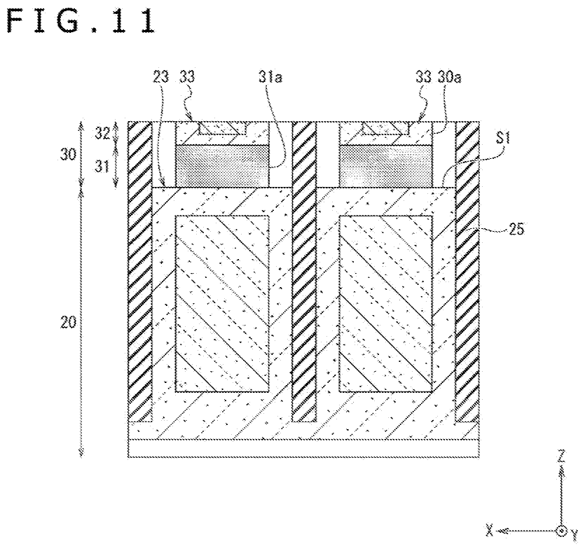

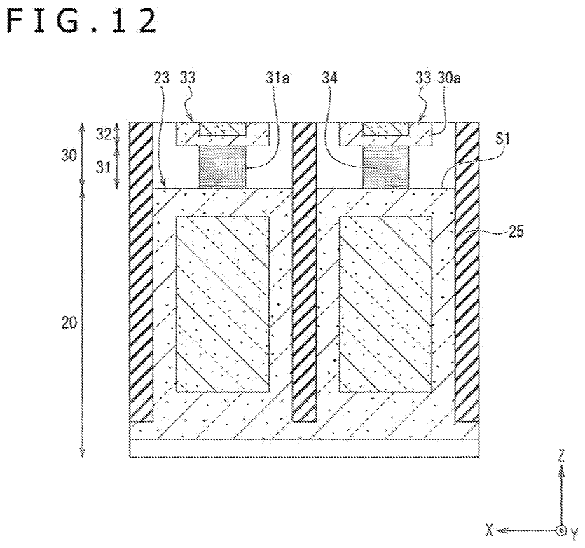

After that, as illustrated in FIG. 11, the sacrificial layer 30b is removed. Then, as illustrated in FIG. 12, the first layer 31 in the element formation region 33 is selectively etched. More specifically, the difference in etching rate in a selected etchant between the material of the first semiconductor layer 20, the material of the first layer 31, and the material of the second layer 32 is utilized to selectively etch the first layer 31 among the first semiconductor layer 20, the first layer 31, and the second layer 32. Here, the material of the first layer 31 is silicon germanium whose etching rate in a selected etchant is higher than that of silicon forming the first semiconductor layer 20 and the second layer 32. Further, at this time, the material of the first layer 31 is etched from the surface facing in the direction vertical to the stacking direction, that is, a side surface 31a. In other words, the material of the first layer 31 is etched from the direction vertical to the stacking direction of the first layer 31. Besides, the first layer 31 after etching corresponds to the channel section 34. Further, through this process, the side surface 31a recedes. Hence, as illustrated in the longitudinal sectional view of FIG. 12, the groove 30a has such a shape that the portion adjacent to the channel section 34 spreads in the direction vertical to the Z direction.

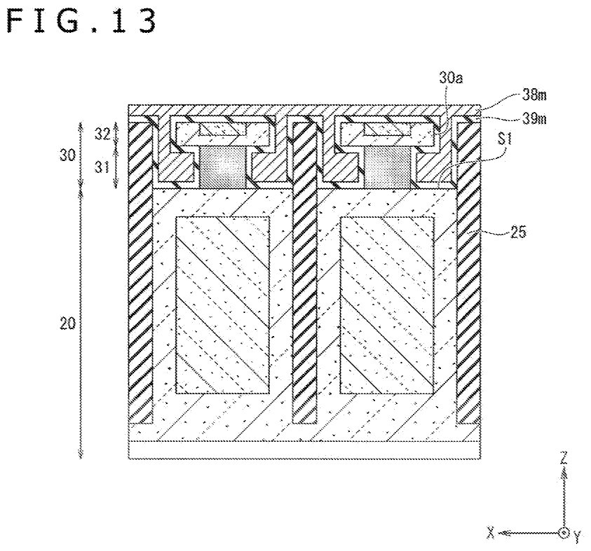

Next, as illustrated in FIG. 13, an insulating film 39m forming the insulating film 39 and a gate material 38m forming the transfer gate electrode 38 are sequentially stacked in this order on the exposed surfaces of the first semiconductor layer 20 and the second semiconductor layer 30. With this, the groove 30a is filled with the gate material 38m through the insulating film 39m. Note that, in the first embodiment, aluminum, which is metal, is stacked as the gate material 38m. Metal has good embeddability. Hence, even when the portion of the groove 30a adjacent to the channel section 34 spreads in the direction vertical to the Z direction, the groove 30a can be filled with the gate material 38m favorably.

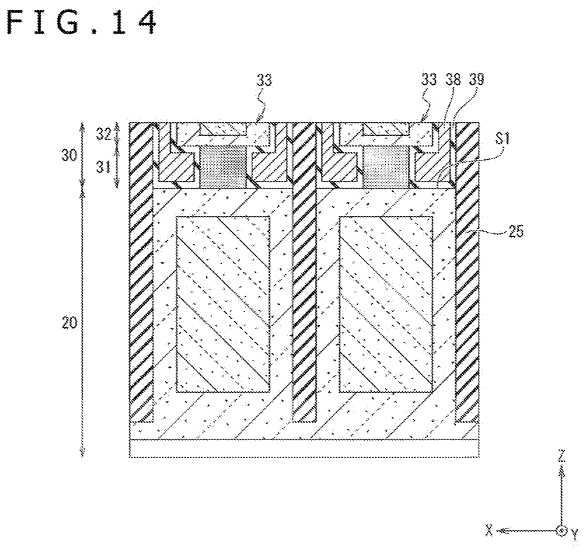

Then, as illustrated in FIG. 14, unnecessary portions of the insulating film 39m and the gate material 38m are removed using a known method such as etch back, although this is not limitative. Through these processes, the transfer gate electrode 38 is formed in the region adjacent to the second semiconductor layer 30 (first layer 31 and second layer 32) through the insulating film 39. The transfer gate electrode 38 allows formation of a channel extending in the stacking direction of the first semiconductor layer 20 and the second semiconductor layer 30, between the photoelectric conversion section 22 provided in the first semiconductor layer 20 and the charge accumulation region 37 provided in the second semiconductor layer 30. Note that the process of removing unnecessary portions of the insulating film 39m may be performed before the gate material 38m is stacked.

After that, the first wiring layer 40 illustrated in FIG. 4A is formed. The contact 44 of the first wiring layer 40 is formed to be electrically connected at one end thereof in the Z direction to the charge accumulation region 37. Then, the first semiconductor layer 20 is polished from the light incident surface side, using a CMP (Chemical Mechanical Polishing) method or the like, to be thinned, and after that, the condensing layer 70 is formed on the light incident surface side.

After that, the fifth surface S5 of the first wiring layer 40 is overlaid on and bonded with the sixth surface S6 of the second wiring layer 50 that is separately prepared and stacked on the third semiconductor layer 60. With this, the photodetector 1 is almost completed. The photodetector 1 is formed in each of multiple chip formation regions partitioned by scribe lines (dicing lines) on a semiconductor substrate. Then, the multiple chip formation regions are divided along the scribe lines into individual pieces, thereby forming the semiconductor chip 2 having mounted thereon the photodetector 1.

### Main Effects of First Embodiment

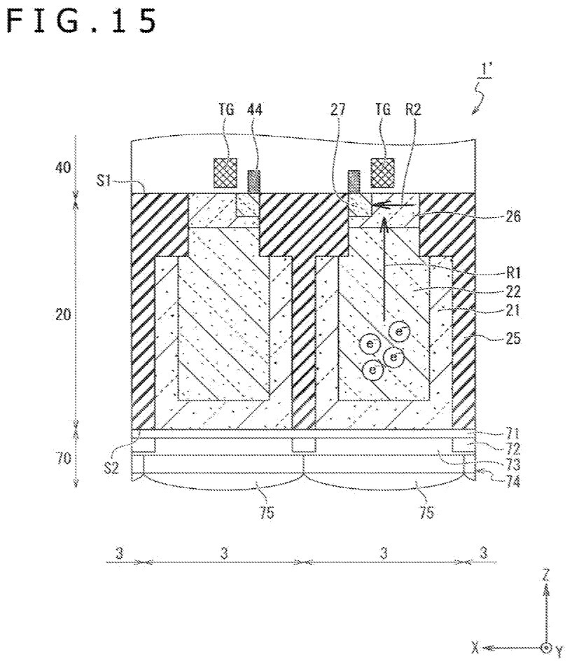

Now, main effects of the first embodiment are described. However, before that, a photodetector 1′ according to a comparative example is described with reference to FIG. 15.

In the photodetector 1′, the charge accumulation region 27 of the second conductivity type, for example, the n-type, is provided within the first semiconductor layer 20, as with the photoelectric conversion section 22. That is, the charge accumulation region 27 is, as with the photoelectric conversion section 22, a region of the first semiconductor layer 20. Since both the charge accumulation region 27 and the photoelectric conversion section 22 are provided in the first semiconductor layer 20, a transfer channel of the transfer transistor TR is also formed within the first semiconductor layer 20.

In the photodetector 1′, since the charge accumulation region 27, the transfer channel, and the photoelectric conversion section 22 are all formed within the first semiconductor layer 20, the volume occupied by the photoelectric conversion section 22 inside the first semiconductor layer 20 is reduced, leading to a decrease in saturation charge accumulation amount (Qs) inside the pixel due to pixel miniaturization in some cases.

As a method of suppressing a decrease in Qs, there is a method that expands the region occupied by the photoelectric conversion section 22 along the thickness direction of the first semiconductor layer 20. However, in this method, it is necessary to inject impurities into a deep position in the thickness direction of the first semiconductor layer 20 in order to form the photoelectric conversion section 22. In that case, it is necessary to inject impurities into the first semiconductor layer 20 with high energy. Injecting impurities with high energy may possibly lead to defects in the semiconductor layer and deterioration of noise characteristics such as white spots and dark current. Besides, how deep impurities can be injected in the thickness direction of the first semiconductor layer 20 depends on impurity injection devices.

Further, as another method of suppressing a decrease in Qs, there is a method that increases the concentration difference of impurities between the semiconductor region 21 of the first conductivity type, for example, the p-type, and the photoelectric conversion section 22 of the second conductivity type, for example, the n-type, thereby deepening the potential of the photoelectric conversion section 22. In that case, signal charges are required to be first transferred from a deep potential position of the photoelectric conversion section 22 along a transfer path R1 illustrated in FIG. 15 toward the semiconductor region 26 of the first conductivity type, for example, the p-type, provided closer to the first surface S1. Then, after that, the signal charges are transferred toward the charge accumulation region 27 along a transfer path R2 different from the transfer path R1.

However, simply deepening the potential of the photoelectric conversion section 22 may possibly lead to transfer errors of signal charges. More specifically, there is a possibility of transfer errors of signal charges along the transfer path R1. Besides, in order to suppress such transfer errors, it is necessary to control the amount of modulation of the potential of the semiconductor layer by a transfer gate electrode TG of the transfer transistor TR to modulate the photoelectric conversion section 22 to a deeper position. However, increasing the amount of modulation of the potential of the semiconductor layer may possibly lead to deterioration of the controllability of signal charge transfer. This is more specifically described below.

In the photodetector 1′, the transfer gate electrode TG is adjacent to the charge accumulation region 27, and hence, there is a possibility of dark current noise generated due to strong charges during control of the transfer gate electrode TG (during modulation with the transfer transistor TR in the on state). More specifically, there is a possibility that, with a large concentration difference of impurities between the p-type semiconductor region 26 and the n-type charge accumulation region 27, strong charges during control of the transfer gate electrode TG adjacent to the charge accumulation region 27 may affect the concentration difference, thereby generating dark current noise. Due to the on and off of the transfer transistor TR, the potential of a p-n junction between the semiconductor region 26 and the charge accumulation region 27 changes to affect the noise characteristics.

Further, even when the semiconductor region is not modulated, that is, in a case where the transfer transistor TR is in the off state, there is a possibility of leakage current flowing toward the charge accumulation region 27. More specifically, in the photodetector 1′, both the charge accumulation region 27 and the photoelectric conversion section 22 are formed within the first semiconductor layer 20 through impurity injection, and the boundary between the charge accumulation region 27 and the photoelectric conversion section 22 is thus not clear, and hence, there is a possibility of signal charges flowing into the charge accumulation region 27 as leakage current even without modulation of the semiconductor layer. Besides, in the photodetector 1′, there is a possibility of deterioration of an S/N ratio.

In this way, in the photodetector 1′, there is a possibility that it may become difficult to achieve both Qs security and the transfer characteristics in a case where pixel miniaturization advances.

In contrast to this, in the photodetector 1 according to the first embodiment of the present technology, on the first semiconductor layer 20, the first layer 31 and the second layer 32 are stacked in this order as the second semiconductor layer 30, the first layer 31 is used as the channel section 34 in which a channel of the transfer transistor TR is formed, and the second layer 32 is provided with the charge accumulation region 37. In this way, the channel section 34 in which a channel is formed and the charge accumulation region 37 are provided in regions other than the first semiconductor layer 20, and hence, a decrease in the volume of the photoelectric conversion section 22 can be suppressed. This makes it possible to suppress a decrease in Qs even when the pixel 3 is miniaturized.

Further, in the photodetector 1 according to the first embodiment of the present technology, the photoelectric conversion section 22, the channel section 34, and the charge accumulation region 37 are provided in this order along the Z direction. Hence, the direction of collecting signal charges from a deep potential position of the photoelectric conversion section 22 and the direction of transferring the collected signal charges to the charge accumulation region 37 match, that is, both of the directions are along the transfer path R of FIG. 4A. This allows signal charges to flow smoothly.

Moreover, in the photodetector 1 according to the first embodiment of the present technology, the material of the channel section 34 is different from the materials of the photoelectric conversion section 22 and the charge accumulation region 37. Thus, in addition to potential control by the transfer transistor TR, the difference in band structure between the different materials is utilized to suppress the flow of signal charges. In addition, since the photoelectric conversion section 22, the channel section 34, and the charge accumulation region 37 are provided in separate semiconductor layers, their boundaries are clear. Therefore, in a case where the transfer transistor TR is in the off state, the flow of signal charges can further be suppressed. This makes it possible to suppress the occurrence of leakage current.

Further, in the photodetector 1 according to the first embodiment of the present technology, the transfer gate electrode 38 is provided to surround the channel section 34 in plan view. With this, the channel section 34 is modulated entirely in the circumferential direction of the side surface 34a, and hence, a wider region is modulated. This allows signal charges to flow smoothly.

Moreover, in the photodetector 1 according to the first embodiment of the present technology, the channel section 34 has a diameter smaller than that of the accumulation section 35, and regarding the transfer gate electrode 38, the second section 382 adjacent to the side surface 34a of the channel section 34 has an inner diameter smaller than that of the first section 381 adjacent to the side surface 35a of the accumulation section 35 through the insulating film 39. Therefore, modulation of the channel section 34 can be controlled more effectively. More specifically, the channel section 34 can be modulated up to near the center, more preferably, up to the center, under control, thereby allowing signal charges to flow more smoothly and making it easier to perform control to stop the flow of signal charges. In addition, since the diameter of the accumulation section 35 is larger than the diameter of the channel section 34, a decrease in the region occupied by the charge accumulation region 37 can be suppressed. This makes it possible to suppress a decrease in the amount of signal charge accumulated in the charge accumulation region 37.

Further, in the photodetector 1 according to the first embodiment of the present technology, the charge accumulation region 37 is relatively distant from the transfer gate electrode 38. Therefore, it is possible to reduce an impact of control of the transfer gate electrode 38 on the charge accumulation region 37 and a p-n junction between the n-type charge accumulation region 37 and the p-type semiconductor region 36 around the charge accumulation region 37.

Moreover, in the photodetector 1 according to the first embodiment of the present technology, the charge accumulation region 37 is surrounded by the semiconductor region 36 exhibiting the conductivity type different from that of the charge accumulation region 37.

Therefore, electrons generated due to defects at the interface of the semiconductor region can be prevented from flowing into the charge accumulation region 37 as dark current.

### Modified Example 1 of First Embodiment

Modified Example 1 of the first embodiment of the present technology is described below. The photodetector 1 according to Modified Example 1 of the first embodiment is different from the above-mentioned photodetector 1 according to the first embodiment in the material of the first semiconductor layer 20 and the material of the second semiconductor layer 30, while the configuration of the photodetector 1 other than those is basically similar to the configuration of the above-mentioned photodetector 1 of the first embodiment. Note that the components already described are denoted by the same reference signs, and the description thereof is omitted. Note that, in Modified Example 1 of the first embodiment, FIG. 4A to FIG. 4C of the first embodiment are reused.

### Material of First Semiconductor Layer

By changing the material of the photoelectric conversion section 22, sensitivity to a wavelength of light changes. Therefore, it is sufficient to select the material of the first semiconductor layer 20 (photoelectric conversion section 22) according to the wavelength of light to be detected. For example, for light such as visible light or infrared light, a material specialized for the light is selected, thereby allowing the photodetector 1 to detect light of a desired wavelength. As the material of the first semiconductor layer 20, for example, silicon can be used for the case of detecting visible light, and silicon germanium can be used for the case of detecting infrared light, although there are not limitative.

### Material of First Layer

The material of the first layer 31 can be combined with the material of the first semiconductor layer 20, and it is sufficient to select a material that allows the first layer 31 to selectively be etched. The material of the first layer 31 can be selected from points of view of crystal structure and lattice count, for example, although this is not limitative. More specifically, from the points of view of crystal structure and lattice count, for example, a material that can be epitaxially grown on the material of the first semiconductor layer 20 can be selected, although this is not limitative.

Further, it is sufficient to determine the film thickness of the first layer 31 according to the combination of the material of the first semiconductor layer 20 and the material of the first layer 31, for example. In general, as the difference in lattice count between materials increases, a film thickness that corresponds to the critical film thickness decreases. Therefore, it is sufficient to adjust the film thickness according to the materials to be combined.

### Material of Second Layer

The material of the second layer 32 can be combined with the material of the first layer 31, and a material that allows the first layer 31 to selectively be etched can be used.

### Example

Now, several examples are given regarding the combination of the material of the first semiconductor layer 20, the material of the channel section 34, and the material of the charge accumulation region 37, although they are not limitative.

### Example 1

The combination of the material of the first semiconductor layer 20, the material of the channel section 34, and the material of the charge accumulation region 37 is a combination of group IV semiconductors containing group IV elements. Representative examples of group IV elements include, but are not limited to, carbon (C), silicon (Si), germanium (Ge), and tin (Sn). Also in the above-mentioned first embodiment, the combination of the material of the first semiconductor layer 20, the material of the channel section 34, and the material of the charge accumulation region 37 is a combination of group IV semiconductors. Note that, as other combinations of group IV semiconductors, there are also combinations described in Example 2 to Example 4 below.

### Example 2

The first semiconductor layer 20 and the charge accumulation region 37 include silicon germanium, and the channel section 34 includes silicon. By using different etchants, the etching rate of the silicon forming the channel section 34 can be made higher than the etching rate of the silicon germanium forming the first semiconductor layer 20 and the charge accumulation region 37. Further, since the photoelectric conversion section 22 includes silicon germanium, Example 2 can be applied to the photodetector 1 configured to detect light other than visible light, more specifically, infrared light.

### Example 3

All the first semiconductor layer 20, the channel section 34, and the charge accumulation region 37 include silicon. Here, the impurity concentration of the silicon forming the channel section 34 is different from the impurity concentration of the silicon forming the first semiconductor layer 20 and the charge accumulation region 37. By using different impurity concentrations, in a selected etchant, the etching rate of the material of the channel section 34 can be made higher than the etching rate of the material of the first semiconductor layer 20 and the charge accumulation region 37. Hence, in the process of selectively etching the first layer 31 of FIG. 12, the first layer 31 can selectively be etched to form the channel section 34. Since the first semiconductor layer 20, the channel section 34, and the charge accumulation region 37 all include silicon, it is possible to suppress an increase in the number of materials of the photodetector 1 and facilitate the manufacturing process.

Further, even in a case where all of the semiconductor layers, namely, the first semiconductor layer 20, the first layer 31, and the second layer 32, include silicon, the boundaries of the first semiconductor layer 20, the first layer 31, and the second layer 32 are clear. More specifically, the boundaries of the impurity concentrations between them are clear. In this way, the boundaries of the impurity concentrations between them are clear, and hence, in a case where the transfer transistor TR is in the off state, the flow of signal charges to cross the boundaries can be suppressed. This makes it possible to suppress the occurrence of leakage current.

### Example 4

The first semiconductor layer 20, the channel section 34, and the charge accumulation region 37 all include silicon. Further, here, in a selected etchant, the surface facing in the direction vertical to the stacking direction of the material of the channel section 34 has an etching rate higher than that of the first surface S1 of the material of the first semiconductor layer 20. Therefore, in the process of selectively etching the first layer 31 of FIG. 12, the first layer 31 can selectively be etched to form the channel section 34.

More specifically, the first surface S1 of the first semiconductor layer 20 and the side surface 31a of the first layer 31 illustrated in FIG. 12 exhibit different crystal orientations of silicon. Hence, through anisotropic etching utilizing anisotropy of orientation in the selected etchant, the side surface 31a can selectively be etched with respect to the first surface S1. Besides, since the first semiconductor layer 20, the channel section 34, and the charge accumulation region 37 all include silicon, it is possible to suppress an increase in the number of materials of the photodetector 1 and facilitate the manufacturing process.

Further, even in a case where all of the semiconductor layers, namely, the first semiconductor layer 20, the first layer 31, and the second layer 32, include silicon, the boundaries of the first semiconductor layer 20, the first layer 31, and the second layer 32 are clear. More specifically, the boundaries of the impurity concentrations between them are clear. In this way, the boundaries of the impurity concentrations between them are clear, and hence, in a case where the transfer transistor TR is in the off state, the flow of signal charges to cross the boundaries can be suppressed. This makes it possible to suppress the occurrence of leakage current.

### Example 5

The combination of the material of the first semiconductor layer 20, the material of the channel section 34, and the material of the charge accumulation region 37 is a combination of group III-V compound semiconductors containing group III elements and group V elements. Representative examples of group III elements include, but are not limited to, boron (B), aluminum (Al), gallium (Ga), and indium (In). Further, representative examples of group V elements include, but are not limited to, nitrogen (N), phosphorus (P), arsenic (As), and antimony (Sb).

As an example of a combination of group III-V compound semiconductors, for example, the first semiconductor layer 20 can include indium gallium arsenide (InGaAs), and the channel section 34 and the charge accumulation region 37 can include indium phosphide (InP), although this is not limitative. Indium gallium arsenide and indium phosphide can be lattice-matched. Therefore, it is possible to reduce the occurrence of defects during stacking and suppress the generation of noise. Further, in a case where electrons are used as signal charges, a conduction band of indium phosphide with respect to a conduction band of indium gallium arsenide serves as a barrier for electrons, thereby making it possible to suppress leakage in the channel.

### Example 6

The combination of the material of the first semiconductor layer 20, the material of the channel section 34, and the material of the charge accumulation region 37 is a combination of group IV semiconductors and group III-V compound semiconductors.

### Main Effects of Modified Example 1 of First Embodiment

Even with the photodetector 1 according to Modified Example 1 of the first embodiment, effects similar to those of the above-mentioned photodetector 1 according to the first embodiment can be obtained.

Moreover, in the photodetector 1 according to Modified Example 1 of the first embodiment, the material of the first semiconductor layer 20, the material of the channel section 34, and the material of the charge accumulation region 37 are individually selected, thereby making it possible to increase design options of the photodetector 1. For example, by changing the material of the first semiconductor layer 20 provided with the photoelectric conversion section 22, the photodetector 1 can detect light of different wavelengths. Besides, even in such a case, the channel section 34 can selectively be etched by changing the manufacturing method.

### Modified Example 2 of First Embodiment

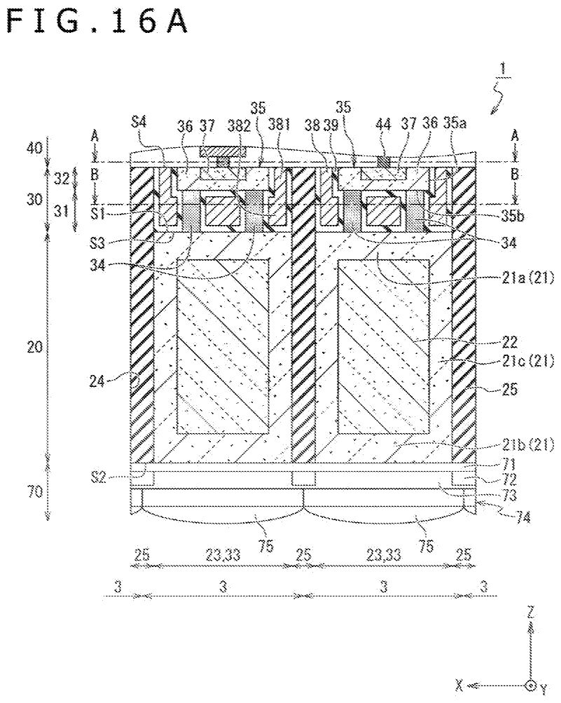

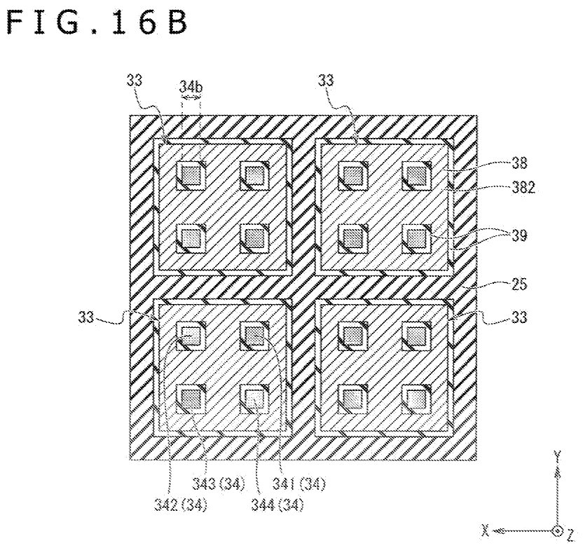

Modified Example 2 of the first embodiment of the present technology illustrated in FIG. 16A and FIG. 16B is described below. The photodetector 1 according to Modified Example 2 of the first embodiment is different from the above-mentioned photodetector 1 according to the first embodiment in that multiple channel sections are provided, while the configuration of the photodetector 1 other than that is basically similar to the configuration of the above-mentioned photodetector 1 of the first embodiment. Note that the components already described are denoted by the same reference signs, and the description thereof is omitted. Note that a transverse sectional view illustrating a cross-sectional structure along a cutting line A-A of FIG. 16A is similar to FIG. 4B, and hence, the illustration thereof is omitted here.

### Channel Section

As illustrated in FIG. 16A, the photodetector 1 includes multiple channel sections 34 for each of the element formation regions 33 (pixels 3). The multiple channel sections 34 are provided to be spaced apart from each other in plan view for the single accumulation section 35. Although FIG. 16B illustrates an example in which the photodetector 1 includes four channel sections 341, 342, 343, and 344, the number of channel sections is not limited to this and is only required to be two or more. Besides, the channel sections 341, 342, 343, and 344 are surrounded entirely in its circumferential direction by the transfer gate electrode 38. When being modulated by the transfer gate electrode 38, the channel sections 341, 342, 343, and 344 function as channels for transferring signal charges between the single photoelectric conversion section 22 and the single charge accumulation region 37. Note that, in a case where the channel sections 341, 342, 343, and 344 are not distinguished from each other, they are simply referred to as the channel section 34. The dimension of a diameter 34b of the channel section 34 is not limited to any particular value as long as the multiple channel sections 34 can fit within the single element formation region 33.

Here, in the channel section 34, the region through which signal charges flow is basically a portion near the side surfaces (peripheral surfaces) of the channel section 34, that is, a region near the insulating film 39 functioning as the gate insulating film of the transfer transistor TR. Hence, by increasing the area of the side surfaces of the channel section 34, the region through which signal charges flow, that is, the effective channel region, can be expanded. In Modified Example 2 of the first embodiment, the multiple channel sections 34 are provided for the single accumulation section 35 to increase the side surface area compared to the case of using the single channel section 34, thereby expanding the effective channel region. Therefore, in Modified Example 2 of the first embodiment, the amount of flowing signal charge can be increased compared to the case of using the single channel section 34.

Further, by setting the diameter 34b of the channel section 34 to several tens of nanometers or less, a quantum confinement effect can be utilized. More specifically, depending on semiconductor materials, by setting the diameter 34b to, for example, 20 nm or less, the quantum confinement effect can be utilized. In this way, when the diameter 34b of the channel section 34 is reduced, the occurrence of leakage current under the off state of the transfer transistor TR can further be suppressed by the quantum confinement effect. Besides, when this quantum confinement effect is utilized, channel-off operation can be achieved even in a state in which impurities are not injected into the channel section 34. Here, when the diameter 34b of the channel section 34 is reduced, the region utilized as a channel is also reduced, leading to a decrease in the amount of signal charge flowing through the single channel section 34.

However, since the multiple channel sections 34 are provided, a decrease in the overall amount of flowing signal charge is suppressed.

### Main Effects of Modified Example 2 of First Embodiment

Even with the photodetector 1 according to Modified Example 2 of the first embodiment, effects similar to those of the above-mentioned photodetector 1 according to the first embodiment can be obtained.

Further, in Modified Example 2 of the first embodiment, the multiple channel sections 34 are provided for the single accumulation section 35 to increase the side surface area compared to the case of using the single channel section 34, thereby expanding the effective channel region. This makes it possible to increase the amount of flowing signal charge compared to the case of using the single channel section 34.

Moreover, in the photodetector 1 according to Modified Example 2 of the first embodiment, the width 34b of the channel section 34 is set to several tens of nanometers or less. Hence, due to the quantum confinement effect, the flow of signal charges under the off state of the transfer transistor TR can further be suppressed. That is, in addition to control other than the voltage between the gate and source of the transfer transistor TR, control of the flow of signal charges, more specifically, control to stop the flow of signal charges, can be performed by using the shape of the channel section 34. This makes it possible to further suppress the occurrence of leakage current.

### Modified Example 3 of First Embodiment

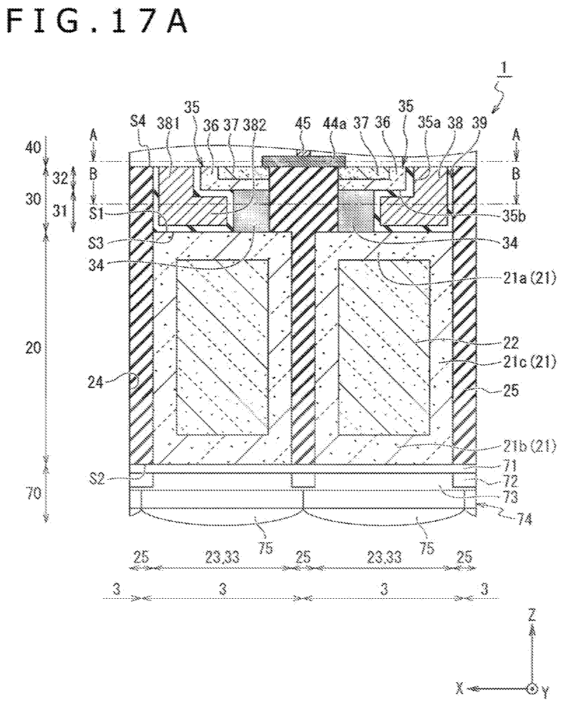

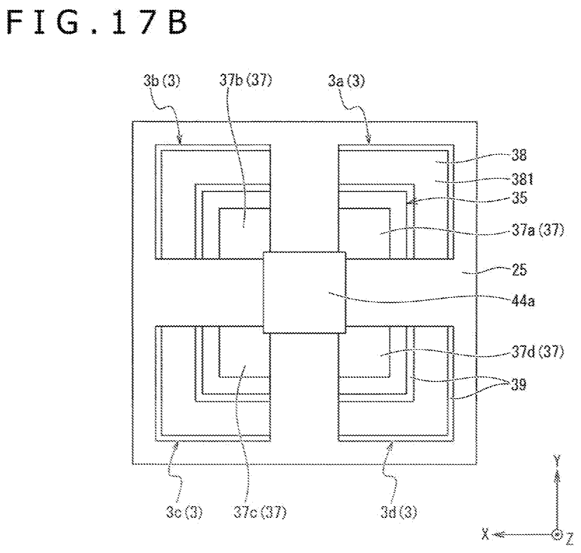

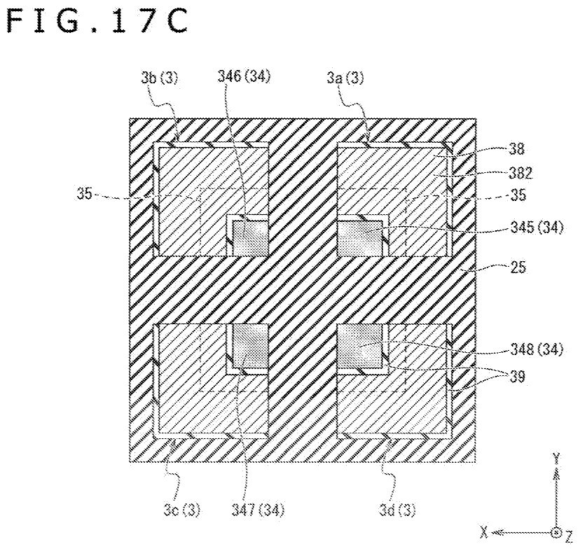

Modified Example 3 of the first embodiment of the present technology illustrated in FIG. 17A, FIG. 17B, and FIG. 17C is described below. The photodetector 1 according to Modified Example 3 of the first embodiment is different from the above-mentioned photodetector 1 according to the first embodiment in that multiple charge accumulation regions 37 share a single contact 44a, while the configuration of the photodetector 1 other than that is basically similar to the configuration of the above-mentioned first embodiment. Note that the components already described are denoted by the same reference signs, and the description thereof is omitted.

The photodetector 1 shares the single contact 44a between the pixels 3. That is, the charge accumulation regions 37 provided in different pixels 3 are electrically connected to each other by the single contact 44a. Although FIG. 17B illustrates an example in which four pixels 3a, 3b, 3c, and 3d, that is, four charge accumulation regions 37a, 37b, 37c, and 37d, share the single contact 44a, the number of charge accumulation regions that share the single contact 44a is not limited to this and is only required to be two or more. Note that, in a case where there is no need to distinguish the pixels 3a, 3b, 3c, and 3d from each other, they are not distinguished and are simply referred to as the pixel 3. Moreover, in a case where there is no need to distinguish the charge accumulation regions 37a, 37b, 37c, and 37d from each other, they are not distinguished and are simply referred to as the charge accumulation region 37.

Signal charges are transferred by modulating channel sections 345, 346, 347, and 348 (see FIG. 17C) of the pixels 3a, 3b, 3c, and 3d sequentially one by one. Even when the multiple charge accumulation regions 37 share the single contact 44a, by modulating the channel sections 345, 346, 347, and 348 sequentially one by one, signal charges can be transferred without signal charge mixing between the pixels. Note that, in a case where there is no need to distinguish the channel sections 345, 346, 347, and 348 from each other, they are not distinguished and are simply referred to as the channel section 34.

### Main Effects of Modified Example 3 of First Embodiment

Even with the photodetector 1 according to Modified Example 3 of the first embodiment, effects similar to those of the above-mentioned photodetector 1 according to the first embodiment can be obtained.

Further, in the photodetector 1 according to Modified Example 3 of the first embodiment, other methods of driving the transfer of signal charges can be adopted, thereby increasing the design options of the photodetector 1.

Note that, in Modified Example 3 of the first embodiment, as illustrated in FIG. 17B and FIG. 17C, the charge accumulation region 37 and the channel section 34 are provided at positions closer to the contact 44a in plan view, but this is not limitative. The charge accumulation region 37 and the channel section 34 may be provided at positions illustrated in FIG. 4B and FIG. 4C. In that case, it is sufficient to increase the area, in plan view, of the contact 44a to an extent that allows the contact 44a to be shared by the charge accumulation regions.

### Modified Example 4 of First Embodiment

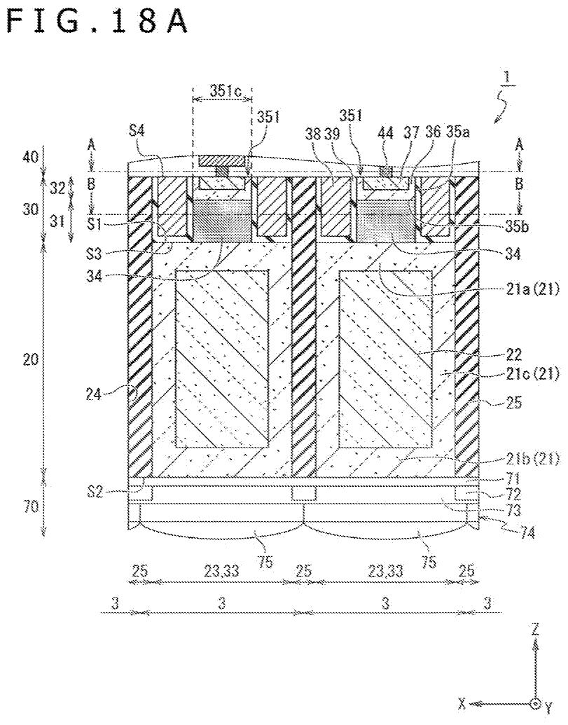

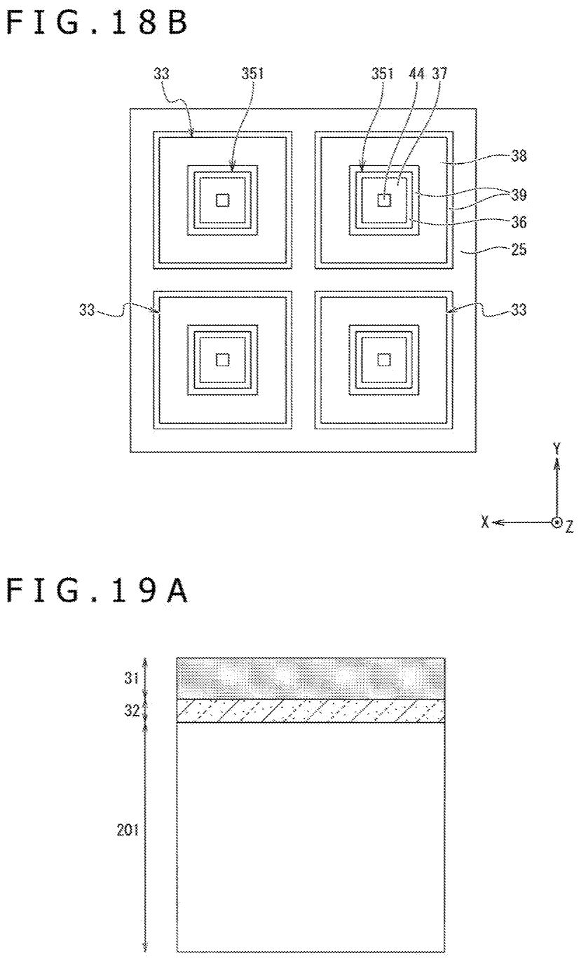

Modified Example 4 of the first embodiment of the present technology illustrated in FIG. 18A and FIG. 18B is described below. The photodetector 1 according to Modified Example 4 of the first embodiment is different from the above-mentioned first embodiment in that the diameter of an accumulation section and the diameter of the channel section are the same, while the configuration of the photodetector 1 other than that is basically similar to the configuration of the above-mentioned first embodiment. Note that the components already described are denoted by the same reference signs, and the description thereof is omitted. Note that a transverse sectional view illustrating a cross-sectional structure along a cutting line B-B of FIG. 18A is similar to FIG. 4C, and hence, the illustration thereof is omitted here.

The photodetector 1 includes an accumulation section 351. As illustrated in FIG. 18A, the accumulation section 351 has a diameter 351c with the same dimension as that of the channel section 34.

Regarding such an accumulation section 351, it is sufficient to form such a groove 30a that the island-shaped element formation region 33 with a diameter that is the width 351c is obtained in the process illustrated in FIG. 7A and FIG. 7B. Besides, the process of selectively etching the first layer 31 illustrated in FIG. 12 is not performed.

Further, the inner diameter of the second section 382 of the transfer gate electrode 38 is the same as the inner diameter of the first section 381.

### Main Effects of Modified Example 4 of First Embodiment

Even with the photodetector 1 according to Modified Example 4 of the first embodiment, effects similar to those of the above-mentioned photodetector 1 according to the first embodiment can be obtained.

Further, in the photodetector 1 according to Modified Example 4 of the first embodiment, the process of selectively etching the first layer 31 is not performed. Hence, when the material of the first semiconductor layer 20, the material of the channel section 34, and the material of the charge accumulation region 37 are selected, there is no need to consider the etching rate for selectively etching the first layer 31, which widens the range of material selection.

Note that, in Modified Example 4 of the first embodiment, the second semiconductor layer 30 includes the two semiconductor layers, namely, the first layer 31 and the second layer 32, but this is not limitative. The second semiconductor layer 30 may include a single semiconductor layer.

Further, in Modified Example 4 of the first embodiment, the accumulation section 351 has a diameter with the same dimension as that of the channel section 34, but this is not limitative. The channel section 34 may have a diameter with the same dimension as that of the accumulation section 35 of the first embodiment, or the channel section 34 and the accumulation section 35 may have diameters with dimensions other than those described above.

### Modified Example 5 of First Embodiment

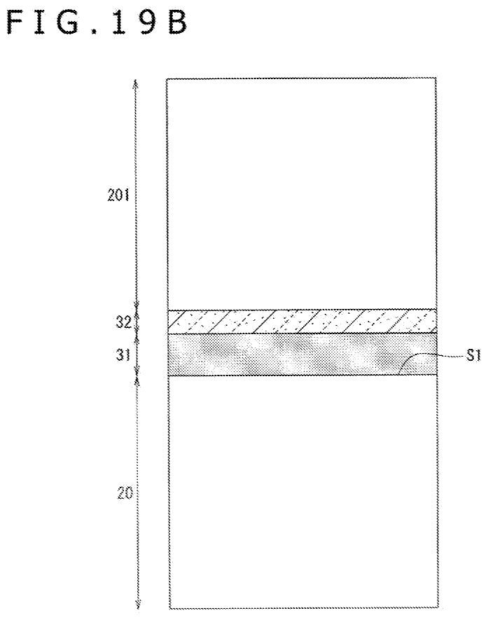

Modified Example 5 of the first embodiment of the present technology illustrated in FIG. 19A and FIG. 19B is described below. The photodetector 1 according to Modified Example 5 of the first embodiment is different from the above-mentioned first embodiment in the process of stacking the first layer 31 and the second layer 32, while the configuration of the photodetector 1 other than that is basically similar to the configuration of the above-mentioned first embodiment. Note that the components already described are denoted by the same reference signs, and the description thereof is omitted.

First, as illustrated in FIG. 19A, a semiconductor layer 201 is prepared separately from the first semiconductor layer 20, and the second layer 32 and the first layer 31 are stacked in this order on the semiconductor layer 201 by epitaxial growth. Then, as illustrated in FIG. 19B, the exposed surface of the first layer 31 is overlaid on the first surface S1 of the first semiconductor layer 20 to be bonded therewith. After that, the semiconductor layer 201 is peeled off from the second layer 32. In this way, the first layer 31 and the second layer 32 are stacked in this order on the first surface S1. With this, the first semiconductor layer 20 with the epitaxially grown second semiconductor layer 30, which is illustrated in FIG. 5, is obtained.

### Main Effects of Modified Example 5 of First Embodiment

Even with the photodetector 1 according to Modified Example 5 of the first embodiment, effects similar to those of the above-mentioned photodetector 1 according to the first embodiment can be obtained.

### Second Embodiment

A second embodiment of the present technology is described below. The photodetector 1 according to the second embodiment is different from the above-mentioned photodetector 1 according to the first embodiment in a separation structure between the pixels 3, while the configuration of the photodetector 1 other than that is basically similar to the configuration of the above-mentioned photodetector 1 of the first embodiment. Note that the components already described are denoted by the same reference signs, and the description thereof is omitted.

### Examples

Now, several examples are given regarding separation between the pixels 3, although this is not limitative.

### Example 1

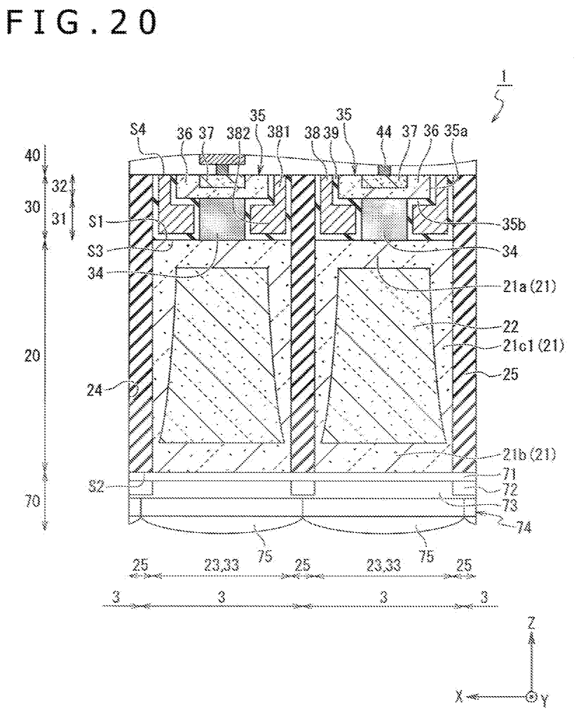

As illustrated in FIG. 20, the first semiconductor layer 20 of the photodetector 1 includes a semiconductor region 21c1 of the second conductivity type, for example, the p-type. The semiconductor region 21c1 is formed by introducing impurities into the first semiconductor layer 20, using known ion implantation techniques.

### Example 2

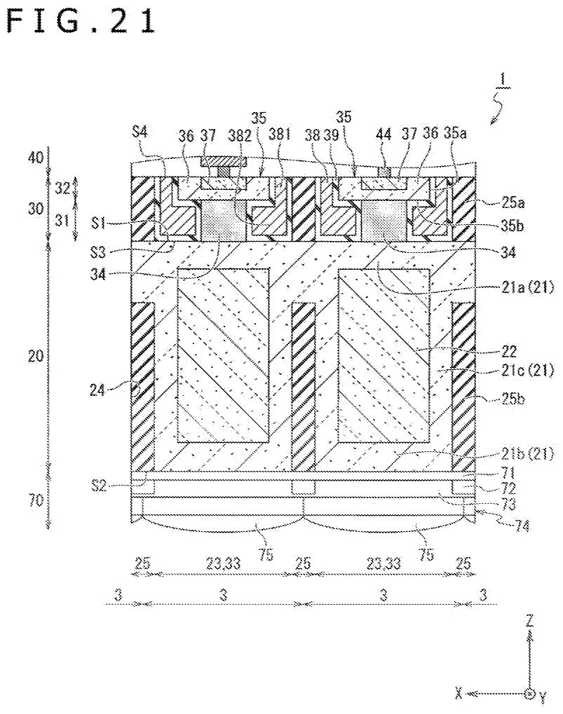

As illustrated in FIG. 21, the photodetector 1 includes a separation region 25a and a separation region 25b. Among these, the separation region 25a partitions the element formation regions 33 from each other. The separation region 25a has a trench separation (STI, Shallow Trench Separation) structure provided to penetrate from the third surface S3 to the fourth surface S4 of the second semiconductor layer 30.

On the other hand, the separation region 25b partitions the photoelectric conversion regions 23 from each other. The separation region 25 has a DTI (Deep Trench Isolation) structure provided in the first semiconductor layer 20 from the second surface S2 side and does not penetrate the first semiconductor layer 20. Further, the element formation region 33 includes a p-type semiconductor region 21c formed using known plasma doping techniques. At least a part of the p-type semiconductor region 21 functions as a separation region (impurity separation region) for separating the photoelectric conversion regions 23 (photoelectric conversion sections 22) from each other.

### Example 3

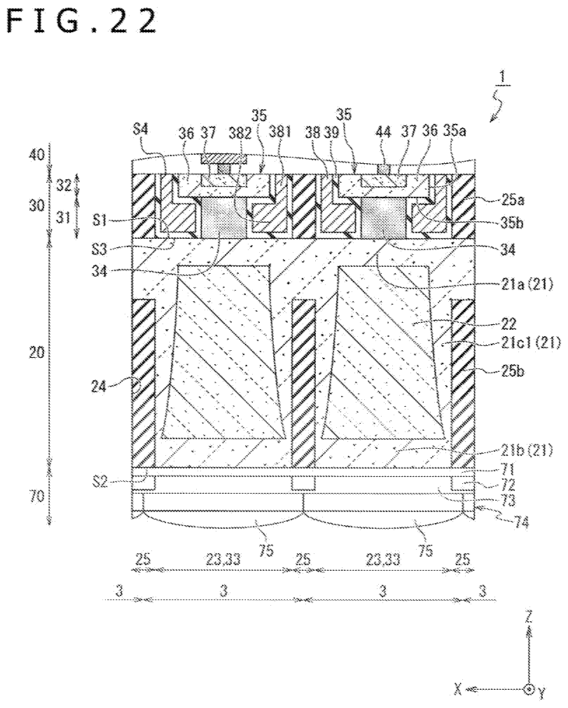

As illustrated in FIG. 22, Example 3 is a combination of Example 1 and Example 2 described above. The first semiconductor layer 20 of the photodetector 1 includes the semiconductor region 21c1 described in Example 1. Moreover, the photodetector 1 includes the separation region 25a and the separation region 25b described in Example 2. At least a part of the p-type semiconductor region 21 functions as a separation region (impurity separation region) for separating the photoelectric conversion regions 23 (photoelectric conversion sections 22) from each other.

### Example 4

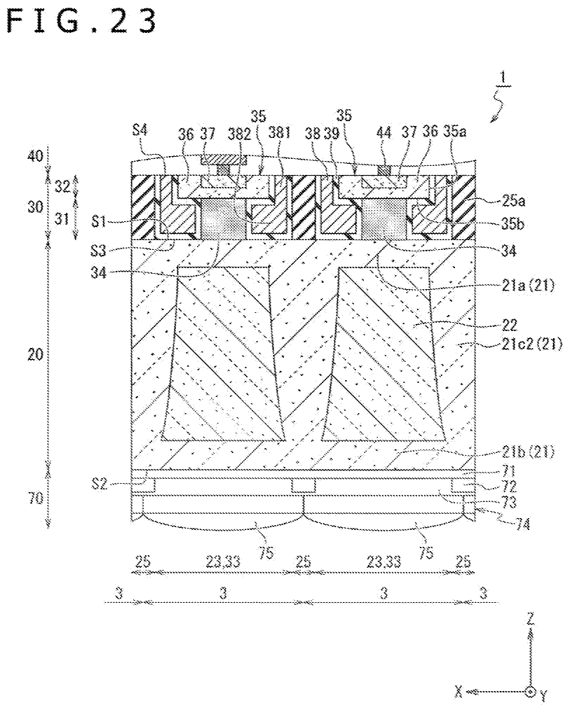

As illustrated in FIG. 23, the photodetector 1 includes the separation region 25a described in Example 3. Further, the first semiconductor layer 20 of the photodetector 1 includes, instead of a trench separation structure, a semiconductor region 21c2 (21) of the second conductivity type, for example, the p-type. The semiconductor region 21c2 is a separation region (impurity separation region) for partitioning the photoelectric conversion regions 23 from each other and is formed by introducing impurities into the first semiconductor layer 20, using known ion implantation techniques.

### Main Effects of Second Embodiment

Even with the photodetector 1 according to the second embodiment, effects similar to those of the above-mentioned photodetector 1 according to the first embodiment can be obtained.

### Third Embodiment

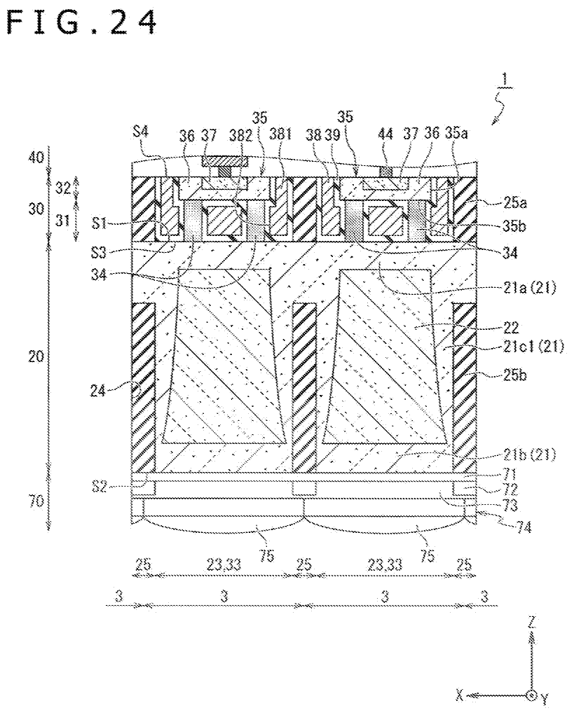

A third embodiment of the present technology illustrated in FIG. 24 is described below. The photodetector 1 according to the third embodiment is a combination of Modified Example 2 of the first embodiment and Example 3 of the second embodiment described above. In this regard, the photodetector 1 according to the third embodiment is different from the above-mentioned photodetector 1 according to the first embodiment. The configuration of the photodetector 1 other than that is basically similar to the configuration of the above-mentioned photodetector 1 of the first embodiment. Note that the components already described are denoted by the same reference signs, and the description thereof is omitted.

The configuration of the second semiconductor layer 30 is the same as the configuration of the second semiconductor layer 30 described above in Modified Example 2 of the first embodiment, and the photodetector 1 includes the multiple channel sections 34 provided to be spaced apart from each other in plan view. The separation structure between the pixels 3 is the same as the separation structure described above in Example 3 of the second embodiment, and the photodetector 1 includes the separation region 25a, the separation region 25b, and the semiconductor region 21c1.

### Main Effects of Third Embodiment

Even with the photodetector 1 according to the third embodiment, effects similar to those of the above-mentioned photodetector 1 according to Modified Example 2 of the first embodiment can be obtained.

Further, in the photodetector 1 according to the third embodiment, since the pixels 3 are separated from each other by the separation region 25b that is a DTI structure, instead of the separation region 25 that is an FTI structure, it is possible to simplify the manufacturing process and further reduce the manufacturing cost.

### Fourth Embodiment

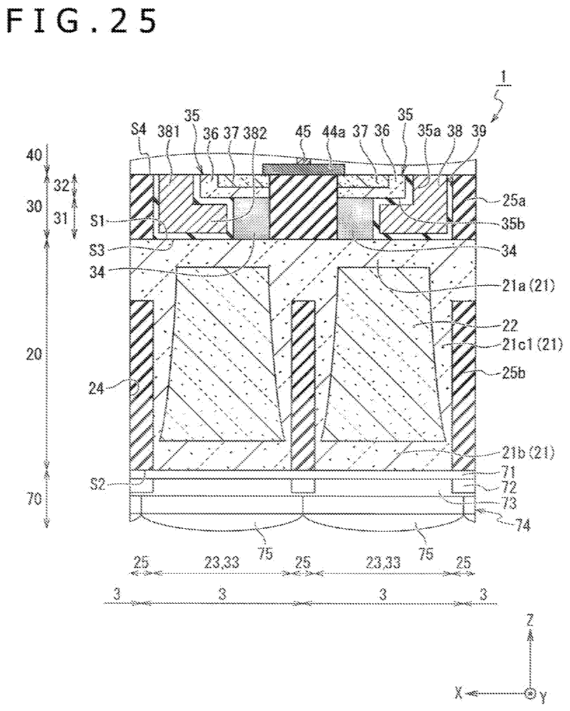

A fourth embodiment of the present technology illustrated in FIG. 25 is described below. The photodetector 1 according to the fourth embodiment is a combination of Modified Example 3 of the first embodiment and Example 3 of the second embodiment described above. In this regard, the photodetector 1 according to the fourth embodiment is different from the above-mentioned photodetector 1 according to the first embodiment. The configuration of the photodetector 1 other than that is basically similar to the configuration of the above-mentioned photodetector 1 of the first embodiment. Note that the components already described are denoted by the same reference signs, and the description thereof is omitted.

The configuration of the second semiconductor layer 30 is the same as the configuration of the second semiconductor layer 30 described above in Modified Example 3 of the first embodiment, and the photodetector 1 shares the single contact 44a between the pixels 3. The separation structure between the pixels 3 is the same as the separation structure described above in Example 3 of the second embodiment, and the photodetector 1 includes the separation region 25a, the separation region 25b, and the semiconductor region 21c1.

### Main Effects of Fourth Embodiment

Even with the photodetector 1 according to the fourth embodiment, effects similar to those of the above-mentioned photodetector 1 according to Modified Example 3 of the first embodiment can be obtained.

Further, in the photodetector 1 according to the fourth embodiment, since the pixels 3 are separated from each other by the separation region 25b that is a DTI structure, instead of the separation region 25 that is an FTI structure, it is possible to simplify the manufacturing process and further reduce the manufacturing cost.

### Fifth Embodiment

### Application Example to Electronic Apparatus

Next, an electronic apparatus according to a fifth embodiment of the present technology illustrated in FIG. 26 is described. An electronic apparatus 100 according to the fifth embodiment includes a photodetector (solid-state imaging device) 101, the optical lens 102, a shutter device 103, a drive circuit 104, and a signal processing circuit 105. The electronic apparatus 100 of the fifth embodiment represents an embodiment in which the above-mentioned photodetector 1 is used for an electronic apparatus (for example, camera) as the photodetector 101.

The optical lens (optical system) 102 forms an image of image light (incident light 106) from an object on an imaging surface of the photodetector 101. With this, signal charges are accumulated in the photodetector 101 over a certain period. The shutter device 103 controls periods of light irradiation and light blocking to the photodetector 101. The drive circuit 104 supplies drive signals for controlling the transfer operation of the photodetector 101 and the shutter operation of the shutter device 103. By drive signals (timing signals) supplied from the drive circuit 104, signals are transferred from the photodetector 101. The signal processing circuit 105 performs various types of signal processing on signals (pixel signals) output from the photodetector 101. Video signals subjected to signal processing are stored in a storage medium such as a memory, or output to a monitor.

With such a configuration, in the electronic apparatus 100 of the fifth embodiment, a decrease in saturation charge accumulation amount in the photodetector 101 is suppressed, and the image quality of video signals can therefore be improved.

Note that the electronic apparatus 100 to which the photodetector 1 can be applied is not limited to cameras, and the photodetector 1 can also be applied to other electronic apparatuses. For example, the photodetector 1 may be applied to imaging devices such as camera modules for mobile devices such as cell phones.

Further, the photodetector 101 may be the photodetector 1 according to any one of or a combination of two or more of the first embodiment to the fourth embodiment and the modified examples and examples thereof.

### Other Embodiments

As described above, the present technology has been described by the first embodiment to the fifth embodiment, but it is to be understood that the present technology is not limited by the statements and drawings included in this disclosure. Various alternative embodiments, examples, and operational techniques may become apparent to those skilled in the art from this disclosure.

For example, the respective technical ideas described in the embodiments from the first embodiment to the fifth embodiment, the modified examples, and the examples can also be combined with each other. Various combinations following the respective technical ideas are possible, and, for example, the materials described in the respective examples of Modified Example 1 of the above-mentioned first embodiment may be applied to Modified Example 2 to Modified Example 5 of the first embodiment, each modified example of the second embodiment, the third embodiment, and the fourth embodiment.

Further, the present technology can be applied to a wide range of photodetectors including not only solid-state imaging devices, which serve as image sensors, but also ranging sensors configured to measure distances, which are also called ToF (Time of Flight) sensors, and the like. A ranging sensor emits irradiation light toward an object, detects reflected light that is the irradiation light reflected by a surface of the object to return, and calculates the distance to the object on the basis of the time of flight from the emission of irradiation light to the reception of reflected light. The structure of the above-mentioned pixel 3 can be adopted as the light-receiving pixel structure of this ranging sensor.

In this way, needless to say, the present technology includes various embodiments and the like not described here. Thus, the technical scope of the present technology is defined only by the matters to define the invention described in CLAIMS supported by the above description.

Further, the effects described herein are merely illustrative and not limitative, and other effects may be provided.

Note that the present technology may adopt the following configurations.
(1)

A photodetector including:
a first semiconductor layer that includes a photoelectric conversion section and that has one surface serving as a light incident surface and another surface serving as a first surface;
a second semiconductor layer that is stacked on the first surface and that includes a charge accumulation region; and
a gate electrode that is adjacent to the second semiconductor layer through an insulating film and that allows formation of a channel extending in a stacking direction of the first semiconductor layer and the second semiconductor layer, between the photoelectric conversion section and the charge accumulation region.
(2)

The photodetector according to (1), in which the charge accumulation region is provided at a position closer to a surface on a side opposite to a side of the first semiconductor layer of the second semiconductor layer.
(3)

The photodetector according to (1),
in which the second semiconductor layer has a stacked structure in which a channel section and an accumulation section are stacked in this order from a side of the first semiconductor layer, and
the charge accumulation region is provided only in the accumulation section among the channel section and the accumulation section.
(4)

The photodetector according to (3), in which a diameter of the channel section is smaller than a diameter of the accumulation section.
(5)

The photodetector according to (4),
in which the gate electrode includes a first section adjacent to a side surface of the accumulation section through the insulating film and a second section adjacent to a side surface of the channel section through the insulating film, and
an inner diameter of the second section is smaller than an inner diameter of the first section.
(6)

The photodetector according to (4), in which, in any etchant, a material of the channel section has a higher etching rate than a material of the first semiconductor layer and a material of the accumulation section.
(7)

The photodetector according to (4), in which, in any etchant, a surface facing in a direction vertical to the stacking direction of a material of the channel section has a higher etching rate than the first surface of a material of the first semiconductor layer.
(8)

The photodetector according to any one of (3) through (7), in which a combination of a material of the first semiconductor layer, a material of the channel section, and a material of the accumulation section includes a combination of group IV semiconductors or a combination of group III-V compound semiconductors.
(9)

The photodetector according to any one of (3) through (8), in which the channel section includes multiple channel sections provided to be spaced apart from each other in plan view for the single accumulation section.
(10)

The photodetector according to any one of (1) through (9), in which the gate electrode surrounds the second semiconductor layer entirely in a circumferential direction in plan view.
(11)

The photodetector according to any one of (1) through (10),
in which each photoelectric conversion section is separated from another photoelectric conversion section by a separation region, and
the separation region includes at least either an insulating material or a semiconductor region into which an impurity has been injected.
(12)

A method of manufacturing a photodetector, including:
preparing a first semiconductor layer;
stacking a second semiconductor layer on a first surface that is a surface on a side opposite to a side of a light incident surface of the first semiconductor layer;
partitioning the second semiconductor layer into island-shaped portions in plan view; and
forming a gate electrode in a region adjacent to the second semiconductor layer through an insulating film, the gate electrode allowing formation of a channel extending in a stacking direction of the first semiconductor layer and the second semiconductor layer, between a photoelectric conversion section provided in the first semiconductor layer and a charge accumulation region provided in the second semiconductor layer.
(13)

The method of manufacturing a photodetector according to (12), further including:
stacking, on the first surface, a first layer and a second layer in this order as the second semiconductor layer;
selectively etching, after partitioning the second semiconductor layer into the island-shaped portions in plan view, the first layer among the first semiconductor layer, the first layer, and the second layer from a direction vertical to the stacking direction of the first layer; and
forming the gate electrode in a region adjacent to the first layer and the second layer through the insulating film.
(14)

An electronic apparatus including:
a photodetector; and
an optical system configured to form an image of image light from an object on the photodetector,
the photodetector including
   a first semiconductor layer that includes a photoelectric conversion section and that has one surface serving as a light incident surface and another surface serving as a first surface,
   a second semiconductor layer that is stacked on the first surface and that includes a charge accumulation region, and
   a gate electrode that is adjacent to the second semiconductor layer through an insulating film and that allows formation of a channel extending in a stacking direction of the first semiconductor layer and the second semiconductor layer, between the photoelectric conversion section and the charge accumulation region.

### REFERENCE SIGNS LIST

1: Photodetector
2: Semiconductor chip
2A: Pixel region
2B: Peripheral region
3: Pixel
4: Vertical drive circuit
5: Column signal processing circuit
6: Horizontal drive circuit
7: Output circuit
8: Control circuit
10: Pixel drive line
11: Vertical signal line
12: Horizontal signal line
13: Logic circuit
15: Readout circuit
20: First semiconductor layer
21, 21a, 21b, 21c, 21c1, 21c2: Semiconductor region
22: Photoelectric conversion section
23: Photoelectric conversion region
25, 25a, 25b: Separation region
Separation region
Separation region
30: Second semiconductor layer
31: First layer
31a: Side surface
32: Second layer
33: Element formation region
34: Channel section
34a: Side surface
34b: Diameter
34b: Width
35: Accumulation section
35a: Side surface
35b: Bottom surface
36: Semiconductor region
37, 37a, 37b, 37c, 37d: Charge accumulation region
38: Transfer gate electrode
39: Insulating film
40: First wiring layer
44, 44a: Contact
50: Second wiring layer
60: Third semiconductor layer
70: Condensing layer
100: Electronic apparatus
102: Optical lens (optical system)

What is claimed is:

1. A photodetector, comprising:
a first semiconductor layer that includes a photoelectric conversion section and that has one surface serving as a light incident surface and another surface serving as a first surface;
a second semiconductor layer that is stacked on the first surface and that includes a charge accumulation region; and
a gate electrode that is adjacent to the second semiconductor layer through an insulating film and that allows formation of a channel extending in a stacking direction of the first semiconductor layer and the second semiconductor layer, between the photoelectric conversion section and the charge accumulation region.

2. The photodetector according to claim 1, wherein the charge accumulation region is provided at a position closer to a surface on a side opposite to a side of the first semiconductor layer of the second semiconductor layer.

3. The photodetector according to claim 1,
wherein the second semiconductor layer has a stacked structure in which a channel section and an accumulation section are stacked in this order from a side of the first semiconductor layer, and
the charge accumulation region is provided only in the accumulation section among the channel section and the accumulation section.

4. The photodetector according to claim 3, wherein a diameter of the channel section is smaller than a diameter of the accumulation section.

5. The photodetector according to claim 4,
wherein the gate electrode includes a first section adjacent to a side surface of the accumulation section through the insulating film and a second section adjacent to a side surface of the channel section through the insulating film, and
an inner diameter of the second section is smaller than an inner diameter of the first section.

6. The photodetector according to claim 4, wherein, in any etchant, a material of the channel section has a higher etching rate than a material of the first semiconductor layer and a material of the accumulation section.

7. The photodetector according to claim 4, wherein, in any etchant, a surface facing in a direction vertical to the stacking direction of a material of the channel section has a higher etching rate than the first surface of a material of the first semiconductor layer.

8. The photodetector according to claim 3, wherein a combination of a material of the first semiconductor layer, a material of the channel section, and a material of the accumulation section includes a combination of group IV semiconductors or a combination of group III-V compound semiconductors.

9. The photodetector according to claim 3, wherein the channel section includes multiple channel sections provided to be spaced apart from each other in plan view for the single accumulation section.

10. The photodetector according to claim 1, wherein the gate electrode surrounds the second semiconductor layer entirely in a circumferential direction in plan view.

11. The photodetector according to claim 1,
wherein each photoelectric conversion section is separated from another photoelectric conversion section by a separation region, and
the separation region includes at least either an insulating material or a semiconductor region into which an impurity has been injected.

12. A method of manufacturing a photodetector, comprising:
preparing a first semiconductor layer;
stacking a second semiconductor layer on a first surface that is a surface on a side opposite to a side of a light incident surface of the first semiconductor layer;
partitioning the second semiconductor layer into island-shaped portions in plan view; and
forming a gate electrode in a region adjacent to the second semiconductor layer through an insulating film, the gate electrode allowing formation of a channel extending in a stacking direction of the first semiconductor layer and the second semiconductor layer, between a photoelectric conversion section provided in the first semiconductor layer and a charge accumulation region provided in the second semiconductor layer.

13. The method of manufacturing a photodetector according to claim 12, further comprising:
stacking, on the first surface, a first layer and a second layer in this order as the second semiconductor layer;
selectively etching, after partitioning the second semiconductor layer into the island-shaped portions in plan view, the first layer among the first semiconductor layer, the first layer, and the second layer from a direction vertical to the stacking direction of the first layer; and
forming the gate electrode in a region adjacent to the first layer and the second layer through the insulating film.

14. An electronic apparatus, comprising:
a photodetector; and
an optical system configured to form an image of image light from an object on the photodetector,
the photodetector including
a first semiconductor layer that includes a photoelectric conversion section and that has one surface serving as a light incident surface and another surface serving as a first surface,
a second semiconductor layer that is stacked on the first surface and that includes a charge accumulation region, and
a gate electrode that is adjacent to the second semiconductor layer through an insulating film and that allows formation of a channel extending in a stacking direction of the first semiconductor layer and the second semiconductor layer, between the photoelectric conversion section and the charge accumulation region.
